(19) United States
(12) Patent Application Publication
(10) Pub. No.: US 2025/0356084 A1
(43) Pub. Date: Nov. 20, 2025

(54) Systems and Methods for Multi-modal Prediction of Composite Properties

(71) Applicant: Rutgers, The State University of New Jersey, New Brunswick, NJ (US)

(72) Inventors: Mohit Agarwal, Pearland, TX (US); Assimina A. Pelegri, East Brunswick, NJ (US)

(21) Appl. No.: 19/209,731

(22) Filed: May 15, 2025

Related U.S. Application Data
(60) Provisional application No. 63/647,998, filed on May 15, 2024.

(51) Int. Cl. G06F 30/27; G06F 30/23

(52) U.S. Cl. CPC G06F 30/27; G06F 30/23

(57) ABSTRACT

Embodiments perform multi-modal prediction of composite properties. A first mode input representing mechanical characteristic(s) of a composite sample is (i) transformed into material property definition(s) of physics-based model(s) or (ii) used to encode material property definition(s) in input variable(s) of a machine learning (ML) model. A second mode input representing morphological characteristic(s) of the sample is (i) transformed into phase volume parameter(s) of the physics-based model(s) or (ii) used to encode phase volume parameter(s) in the input variable(s) of the ML model. A third mode input associated with the sample is (i) transformed into electrical conductivity parameter(s) of the physics-based model(s) or (ii) used to encode electrical conductivity parameter(s) in the input variable(s) of the ML model. Using the physics-based model(s) or the ML model, property(ies) of the sample are predicted.

### RELATED APPLICATION

This application claims the benefit of U.S. Provisional Application No. 63/647,998, filed on May 15, 2024. The entire teachings of the above application are incorporated herein by reference.

### BACKGROUND

Interest in computational models for soft composites, e.g., soft tissue such as brain tissue, as well as hard composites, has grown over time.

### SUMMARY

While interest in computational models for composites has grown over time, existing approaches are inadequate because, for instance, they fail to accurately depict complex underlying composite mechanics, owing to, e.g., high variability in material properties, different constitutive material modeling, and experimental setup. For instance, conventional tissue experiments may be affected by, e.g., geography, lab setup, and/or experimental setup, as well as choice of accuracy and/or degree of computational accuracy in a modeling choice. The literature thus reveals a host of values for material properties. none of which converge or which cannot converge in fact to one single material property. Therefore, functionality with improved accuracy for predicting composite properties is needed. Embodiments deliver such functionality.

Embodiments provide solutions for multi-modal modeling of composites, e.g., organic materials—in humans or animals—such as brain and other central nervous system (CNS) tissue, blood vessels (e.g., injected with dye for computed tomography (CT) scans), cardiac tissue, muscle, and fiber tissues, etc., as well as other composites including without limitation soft polymers, nonlinear soft composites, and inorganic composite materials such as radial tires. Further, a novel heterogenous model workflow of embodiments can be utilized for complex material, e.g., soft and hard composites, modeling and material discovery and/or synthesis, e.g., tissue synthesis.

It should be emphasized that embodiments can apply not only to soft composites, but also to hard materials. Non-limiting examples of hard composites that can be analyzed and/or engineered according to principles of embodiments include meta materials, nano electrodes (e.g., for battery cell material design), and hybrid piezoelectric materials.

An example embodiment is directed to a computer-implemented method for physics-based multi-modal prediction of composite properties. The method includes transforming a first mode input into at least one material property definition of at least one physics-based model, e.g., configuring, engineering, or formulating the at least one material property definition based on the first mode input. The first mode input represents at least one mechanical characteristic of a composite sample. The method further includes transforming a second mode input into at least one phase volume parameter of the at least one physics-based model, e.g., configuring, engineering, or formulating the at least one phase volume parameter based on the second mode input. The second mode input represents at least one morphological characteristic of the composite sample. The method further includes transforming a third mode input into at least one electrical conductivity parameter of the at least one physics-based model, e.g., configuring, engineering, or formulating the at least one electrical conductivity parameter based on the third mode input. The third mode input is associated with the composite sample. The method further includes, using the at least one physics-based model, predicting at least one property of the composite sample.

In an example embodiment, the composite sample may be a soft composite sample or a hard composite sample.

According to an example embodiment, the at least one physics-based model may include at least one finite element (FE) model, and the predicting may include, via a FE solver, using the at least one FE model, predicting the at least one property.

In an example embodiment, the predicted at least one property of the composite sample may include at least one of a mechanical property, an electrical property, and a biochemical property.

According to an example embodiment, the method may further include, based on the first mode input, the second mode input, and the third mode input, via at least one generative ML/AI model, producing a set of synthesized physics-based models. Predicting the at least one property of the composite sample may be performed using the set of synthesized physics-based models. In one such embodiment, the at least one generative ML/AI model includes at least one of a Retrieval-Augmented Generation (RAG) model and a generative adversarial network (GAN) model. According to another such embodiment, the producing may be based on a first constraint set, a second constraint set, and a third constraint set. The first constraint set may correspond to the first mode input. The second constraint set may correspond to the second mode input. The third constraint set may correspond to the third mode input. In yet another such embodiment, the first constraint set may include at least one of a shear constraint, a tensile constraint, a compression load constraint, a boundary condition, and a stress value.

Another example embodiment is directed to a computer-implemented method for hybrid multi-modal prediction of composite properties. The method includes encoding, in at least one input variable of a machine learning (ML) model, based on a first mode input, at least one material property definition. The first mode input represents at least one mechanical characteristic of a composite sample. The ML model is trained to predict composite properties based on first mode inputs, second mode inputs, and third mode inputs. The method further includes encoding, in the at least one input variable of the ML model, based on a second mode input, at least one phase volume parameter. The second mode input represents at least one morphological characteristic of the composite sample. The method further includes encoding, in the at least one input variable of the ML model, based on a third mode input, at least one electrical conductivity parameter. The third mode input is associated with the composite sample. The method further includes, using the ML model, predicting at least one property of the composite sample.

In an example embodiment, the method may further include training the ML model based on multiple training data tuples. Each of the multiple training data tuples may include (i) a first mode training input, (ii) a second mode training input, (iii) a third mode training input, and (iv) at least one training property. According to another example embodiment, the method may further include generating at least one training property of a given training data tuple of the multiple training data tuples. The generating may include transforming the first mode training input of the given training data tuple into at least one material property definition of at least one physics-based model. The first mode training input may represent at least one mechanical characteristic of a composite training sample. The generating may further include transforming the second mode training input of the given training data tuple into at least one phase volume parameter of the at least one physics-based model. The second mode training input may represent at least one morphological characteristic of the composite training sample. The generating may further include transforming the third mode training input of the given training data tuple into at least one electrical conductivity parameter of the at least one physics-based model. The third mode training input may be associated with the composite training sample. The generating may further include, using the at least one physics-based model, predicting the at least one training property of the given training data tuple.

According to an example embodiment, the predicted at least one property may include at least one micro-scale property. The method may further include, using at least one homogenization model, transforming the at least one micro-scale property into at least one macro-scale property of the composite sample. In another example embodiment, the at least one homogenization model may include a fast Fourier transform (FFT) model.

In an example embodiment, the method may further include, using an optimization model, constructing a design space based on the predicted at least one property. According to another example embodiment, the method may further include, based on the constructed design space, synthesizing a composite material candidate design. In yet another example embodiment, the method may further include comparing the synthesized composite material candidate design and the composite sample and, based on a result of the comparing, modifying at least one of the first mode input, the second mode input, and the third mode input. According to an example embodiment, the synthesized composite material candidate design may be for a brain-like tissue. In another example embodiment, the optimization model may include at least one of: a genetic model, a grid search model, a space-filling model, a particle swarm model, another multi-objective optimization model, and a generative ML/AI model.

According to an example embodiment, synthesizing the composite material candidate design may include synthesizing one or more composite material candidate designs. The method may further include, using at least one generative ML/AI model, transforming the one or more composite material candidate designs synthesized into one or more optimized composite material candidate designs. In one such embodiment, transforming the one or more composite material candidate designs synthesized may be based on at least one prompt received from a user.

According to an example embodiment, the ML model may be a neural network model, a decision tree model, or a random forest model. In another example embodiment, the at least one input variable may include an input layer of the neural network model.

In an example embodiment, the composite sample may be a human brain tissue sample or an animal brain tissue sample.

According to an example embodiment, the method may further include encoding, in the at least one input variable of the ML model, based on a fourth mode input, at least one additional parameter. The fourth mode input may include at least one of: a biochemical data input, a large language model (LLM) based input, a natural language processing (NLP) based input, a time series input, a sensor input, an equation based input, a video input, a radiation data input, and a patient history input. The ML model may be further trained to predict composite properties based on fourth mode inputs.

In an example embodiment, the second mode input may include at least one of: magnetic resonance elastography (MRE) data, magnetic resonance imaging (MRI) data, diffusion tensor imaging (DTI) data, scanning electron microscope (SEM) data, and CT data.

According to an example embodiment, the third mode input may include (i) at least one graph interconnect characteristic of the composite sample or (ii) a growth model corresponding to the composite sample. In another example embodiment, the method may further include configuring at least one of: (i) a graph branch length parameter, (ii) a branching proliferation criterion, (iii) a branching expansion criterion, and (iv) an interaction parameter, for the growth model.

Another example embodiment is directed to a computer-based system for physics-based multi-modal prediction of composite properties. The system includes a processor and a memory with computer code instructions stored thereon. In such an embodiment, the processor and the memory, with the computer code instructions, are configured to cause the system to implement any embodiments or combination of embodiments described herein.

Yet another example embodiment is directed to a computer-based system for hybrid multi-modal prediction of composite properties. The system includes a processor and a memory with computer code instructions stored thereon. In such an embodiment, the processor and the memory, with the computer code instructions, are configured to cause the system to implement any embodiments or combination of embodiments described herein.

It is noted that embodiments of the methods and systems may be configured to implement any embodiments, or combination of embodiments, described herein.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The foregoing will be apparent from the following more particular description of example embodiments, as illustrated in the accompanying drawings in which like reference characters refer to the same parts throughout the different views. The drawings are not necessarily to scale, emphasis instead being placed upon illustrating embodiments.

FIG. 1 is a flow diagram of a physics-based multi-modal forward process, according to an example embodiment.

FIG. 2 is a flowchart of a method for physics-based multi-modal prediction of composite properties, according to an example embodiment.

FIG. 3 is a flow diagram of a physics-based multi-modal forward process with generative ML/artificial intelligence (AI), according to an example embodiment.

FIG. 4 is a flow diagram of a hybrid multi-modal forward process, according to an example embodiment.

FIG. 5 is a flowchart of a method for hybrid multi-modal prediction of composite properties, according to an example embodiment.

FIG. 6A is representative MRI images from a test subject, according to an example embodiment.

FIG. 6B is representative DTI images from the test subject of FIG. 6A, according to an example embodiment.

FIG. 6C is a sample masked image for fractional anisotropy (FA) measurement in DTI from the test subject of FIG. 6A, according to an example embodiment.

FIG. 7 is a flow diagram of a scalability/homogenization process, according to an example embodiment.

FIG. 8A is a flow diagram of an inverse process, according to an example embodiment.

FIG. 8B is a flow diagram of an inverse process with generative ML/AI, according to an example embodiment.

FIG. 9 is an image of oligodendrocytes arbitrarily tethered to axons, according to an example embodiment.

FIG. 10 is a schematic representation of an oligodendrocyte tethering to axons, according to an example embodiment.

FIG. 11 is an image of a single oligodendrocyte tethering to surrounding axons, according to an example embodiment.

FIG. 12 is an image of prior art sawbones.

FIG. 13 is an image of prior art synthesized brain-like tissues.

FIG. 14 is a flow diagram of a closed-loop/feedback process, according to an example embodiment.

FIG. 15A is a schematic of parallel axons according to an example embodiment.

FIG. 15B is a two-dimensional (2D) representative volume element (RVE) for a triphasic model for the myelinated axons of FIG. 15A.

FIG. 16 is a histogram distribution plot for key variables in a 2D FE method (FEM) viscoelastically (VE) modeled brain white matter (BWM) dataset according to an example embodiment.

FIG. 17 is a block diagram of a forward ML/AI predictive modeling workflow according to an example embodiment.

FIG. 18 is a pair plot visualizing relationships between multiple features in the 2D FEM dataset of FIG. 16.

FIG. 19 is a heatmap representation of a correlation matrix for the synthetic 2D FEM dataset of FIG. 16.

FIG. 20 is a plot illustrating prediction intervals and uncertainty quantification for a Gradient Boosting Decision Trees (GBDT) regressor model according to an example embodiment.

FIG. 21 is a plot of prediction intervals and mean trends for a Light Gradient Boosting Machine (LGBM) regressor model according to an example embodiment.

FIG. 22 is a plot of prediction intervals and mean trends for a random forest regressor model according to an example embodiment.

FIG. 23 is a plot of conformal prediction intervals with random forest regressor model results on a subset of the test synthetic 2D FEM data of FIG. 16.

FIG. 24 is a plot of random forest regression results with conformal prediction intervals according to an example embodiment.

FIG. 25 is a bar plot showing mean absolute SHapley Additive explanations (SHAP) values for feature importance according to an example embodiment.

FIG. 26 is a summary plot of SHAP values for individual predictions according to an example embodiment.

FIG. 27 is a dependence plot illustrating a relationship between a gliaStor feature and its SHAP values according to an example embodiment.

FIGS. 28A-28C are embedding plots showing a distribution of SHAP values according to an example embodiment.

FIGS. 29A and 29B are SHAP force plots on training set and test set data, respectively, according to an example embodiment.

FIG. 30 is a waterfall plot visualizing individual features' contributions to a single prediction according to an example embodiment.

FIG. 31 is a schematic view of a computer network in which embodiments may be implemented.

FIG. 32 is a block diagram illustrating an example embodiment of a computer node in the computer network of FIG. 31.

### DETAILED DESCRIPTION

A description of example embodiments follows.

As used herein, a “representative volume element” (RVE) may refer to a representative geometry at one of multiple different scales. For example, an RVE may be a micro-scale geometry, a meso-scale geometry, a nano-scale geometry, or a macro/continuum-scale geometry. It should be noted that embodiments are not limited to any particular material or scale; rather, embodiments apply to materials and geometries (such as RVEs) across all known scales. Various other types of representative geometries may also be used depending on a given material family of interest and/or modeling industry convention. These may include, for non-limiting examples, “representative elementary volume” (REV), “repeated unit cell” (RUC), and repeated unit volume (RUV). It should further be noted that embodiments are not limited to any particular type of representative geometry; rather, embodiments apply to all known types of representative geometries, e.g., RVEs, REVs, RUCs, and RUVs, etc. For the avoidance of doubt, it is noted that the terms RVE, REV, RUC, and RUV may be used interchangeably herein.

Embodiments provide a novel multi-modal framework for composite (e.g., soft tissue) modeling and characterization by formulating a multi-scale, multi-physical, and data-driven workflow to predict material properties (referred to interchangeably as a “forward” model, stage, phase, schema, or pass). The multi-modal (i.e., utilizing heterogenous data types) workflow may encompass the below three non-limiting example data types to obtain physics-based multi-scale and multi-physics composite (e.g., brain or other soft tissue) computational models, that can be used to predict properties such as mechanical (e.g., stress) and/or electrical (e.g., potential) metrics versus applied strain values:
a) Mechanical data, e.g., strain and stress test data, etc.;
b) Morphological data—i.e., volume fraction (VF) of constituent phases—from, e.g., MRE/MRI scans to define geometry/micro-architectures of composites (e.g., brain matter or similar non-linear composites); and
c) Conductive data—i.e., electrical signals—such as transmitted signals on a matrix of neurons, among other examples.

It should be emphasized that embodiments are not limited to the above three example data types. Rather, any desired combination or permutation of multiple heterogeneous data types may be used.

In addition, embodiments may leverage results from a multi-modal forward model schema into a “inverse” (referred to interchangeably as “reverse”) model workflow to engineer, e.g., meta-materials/soft composite foam blocks, mimicking real-world composites (e.g., tissues/non-linear composites) as just one of many practical applications of results of the novel simulation framework of embodiments. Further, embodiments may provide a forward-inverse cyclic multi-modal workflow with iterative optimizations (i.e., model training) to match experimental results, which can aid immensely in, e.g., tissue synthesis and material discovery applications, to name just a few.

Embodiments also provide a multi-scale, multi-physical, and multi-modal modeling approach for composites, e.g., brain tissue, which offers myriad benefits for non-linear tissue modeling and tissue synthesis applications, among other examples. Further, embodiments may utilize a unique ensemble of multiple model approaches to develop a high-fidelity modeling schema that transforms composite (e.g., tissue) modeling by incorporating mechanical, morphological, and electrical data types as input to physics-based and/or data-driven model workflows that can be used to predict composite (e.g., brain matter) response. Embodiments may also leverage inverse modeling techniques to engineer new materials and tissue based on predicted properties from forward model steps. Moreover, embodiments may employ a self-contained, unified framework that includes models from diverse domains, such as FEM models, AI/ML models, FFT models, and inverse models, among other examples.

The closed loop process of embodiments helps meet a long-standing business/market need in the neurological and bioengineering domains by enabling manufacturing of synthetic composite (e.g., tissue) blocks. Such synthetic/engineered composites can transform testing and characterization of, e.g., brain matter, in experimental research. For instance, the closed loop feedback approach of embodiments can be deployed to validate model composite (e.g., tissue) results with experimental macro-scale (e.g., porcine brain tissue) data to compare model efficacy.

Embodiments offer benefits for numerous industries and applications. For instance, the multi-stage, physics-based and/or data science/ML-driven models of embodiments can aid in composite (e.g., tissue) engineering and synthesis. As another example, embodiments can enhance the process of tissue sensitivity analysis for composites such as brain and other tissues or matter. For other composites like polymers (besides bio tissues), embodiments can aid in material discovery and meta-material composite generation.

Moreover, embodiments can be leveraged for other material, such as complex composites, modeling and characterization. Embodiments provide a multi-physics, multi-scale, and multi-modal solution. For instance, the state-of-the-art high-fidelity solution of embodiments can be used to predict and/or simulate bio-physiological mechanics and/or simulate traumatic injury/load response.

As one example of simulating traumatic brain injury (TBI), conventional “whole head” approaches rely on an assumption of a homogenous material model. However, brain matter is not homogenous—especially white matter (WM). Embodiments thus provide scalable (e.g., multi-scale) models. For instance, according to an example embodiment, if an anisotropy is shown at small-scale, it can then be scaled up for macro-scale too—instead of simply assuming a whole brain to be a homogenous material model type. A corresponding example benefit of embodiments is that simulations and analysis then at macro-scale (i.e., real-world scale) are far more reliable and help administer treatment and mitigation steps for TBI. Moreover, brain damage may initially occur at very small scale, such as the level of single axons. Embodiments can simulate brain trauma more precisely and more accurately than existing techniques. This may offer real-world benefits such as earlier detection and treatment, which in turn may result in significant cost savings, including from, e.g., avoiding the need to provide disability payments to injured soldiers over long timeframes.

The methodology of embodiments is transferrable to many complex materials and composites, such as where complex biophysical, biochemical, mechano-thermal, and/or mechano-electrical factors determine structure integrity and/or microstructure. As part of Industry 4.0, the framework of embodiments enables realization of end-to-end digital thread/digital twin definitions for material manufacturers and researchers.

Embodiments provide a robust and closed loop (e.g., via a feedback mechanism) framework to fit modeled composite (e.g., tissue) properties to real-world composites (e.g., living tissues) as part of an iterative optimization process.

### Example Physics-Based Multi-Modal Forward Process

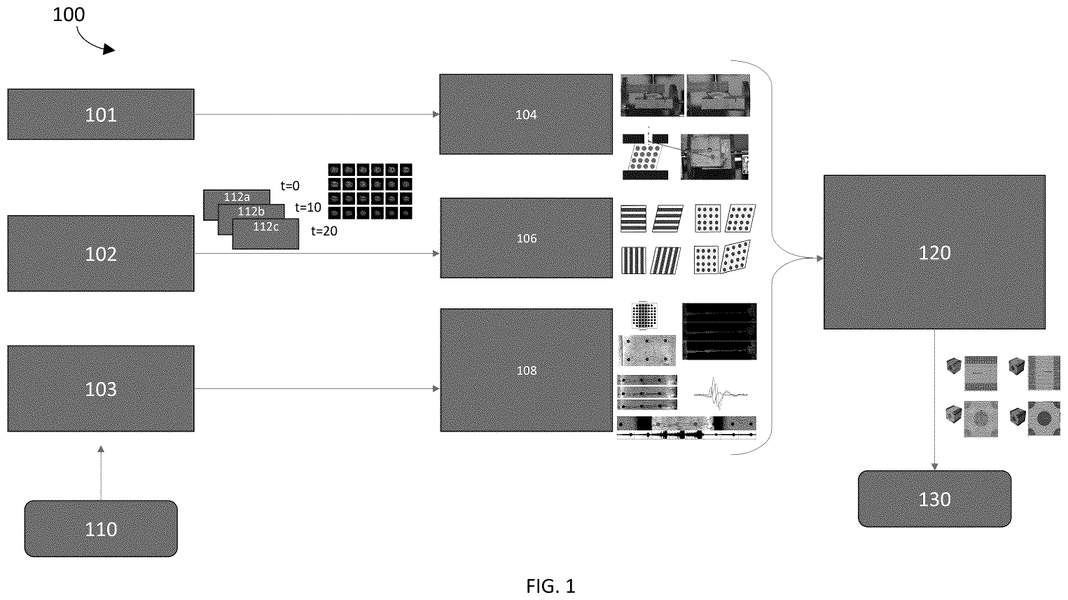

FIG. 1 is a flow diagram of a physics-based multi-modal forward process 100, according to an example embodiment. The process 100 may include an input step 110, a physics-based modeling step 120, and an output step 130. In an example embodiment, the process 100 may be a pure physics-based multi-modal FEM solution.

At the input step 110, mechanical data 101, morphology data 102, and electrical data 103 may be obtained for a composite sample (not shown).

The mechanical data 101 may include, e.g., strain, load (shear, tension, compression, etc.), and other test setup data. In an example embodiment, the data 101 may be used to generate or configure material property definition(s) 104 for physics-based model(s), e.g., FE model(s) or RVE(s). According to another example embodiment, generating the definition(s) 104 may include converting the data 101 to an array format, such as the NumPy® format or other suitable format known to those of skill in the art. The array format conversion may be performed via Excel® or other suitable known tool. Examples of mechanical data are further described in Agarwal, M., et al., “Data-Driven Depiction of Aging Related Physiological Volume Shrinkage in Brain White Matter: An Image Processing Based Three-Dimensional Micromechanical Model,” Journal of Engineering and Science in Medical Diagnostics and Therapy 8, No. 4 (2025), which is herein incorporated by reference in its entirety.

The morphology data 102 may include, e.g., MRE/MRI scans (e.g., brain scans) or SEM image data. In an example embodiment, the data 102 may be, e.g., DTI scans 112a, 112b, and 112c at timesteps of t=0, t=10, and t=20, respectively. According to another example embodiment, the data 102 may be used to control or configure phase volume parameter(s) 106 for physics-based model(s), e.g., FE model(s). For instance, in yet another example embodiment, morphology data 102, e.g., image data, may be converted into a three-dimensional (3D) array (i.e., voxel) format, such as the NumPy format or other suitable format known to those of skill in the art.

The electrical data 103 may be, e.g., conduction and/or neuro-pulse data, and/or may include, e.g., drug/pigment induced neuron excited pulse transmission experimental data. According to an example embodiment, the data 103 may be used to configure or define graph interconnect parameter(s) 108 for physics-based model(s), e.g., FE model(s). For instance, in another example embodiment, the data 103 may include pulse transmission signals that help to achieve an understanding of, e.g., interconnects between neurons, i.e., by graphing neuron networks based on pulse excitation.

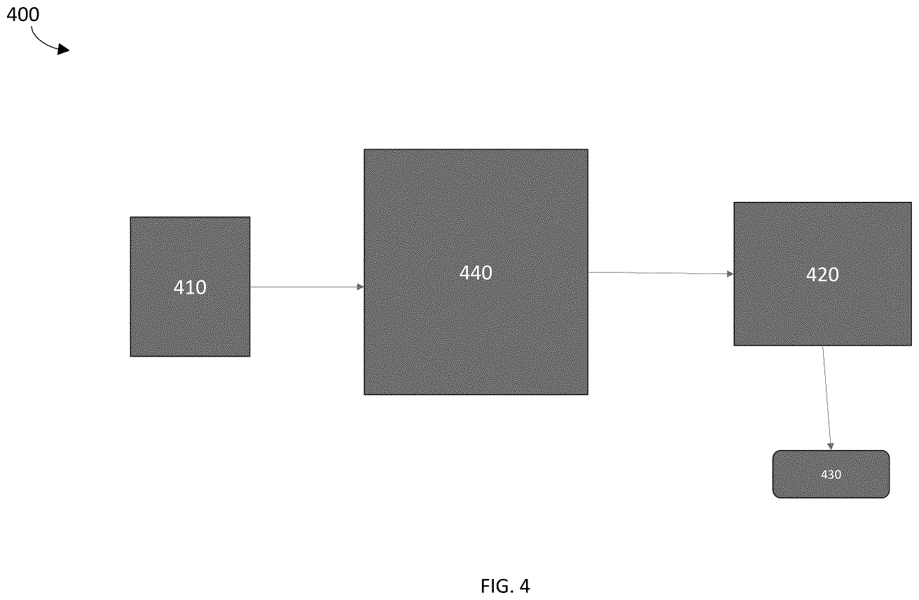

It should be noted that, according to an example embodiment, the input types 101, 102, and/or 103 can be graphical user interface (GUI) or equation scripted inputs defined in a physics-based modeling tool, e.g., a FEM tool such as Abaqus®, COMSOL®, or Ansys® for the physics-based forward process 100 shown in FIG. 1. Similarly, in another example embodiment, the input types 101, 102, and/or 103 can be coded (e.g., via Python™ or other suitable known tool) into a physics-based modeling tool, e.g., a FEM tool such as Abaqus and used in a ML model input layer, e.g., as part of the hybrid process 400 described in more detail hereinbelow in relation to FIG. 4. Examples of scripted electrical data (e.g., the input type 103) are further described hereinbelow and in Appendix A.

To continue, at the physics-based modeling step 120, the material property definition(s) 104, the phase volume parameter(s) 106, and the graph interconnect parameter(s) 108 may be used to build or construct physics-based model(s), e.g., FE model(s). In an example embodiment, the physics-based model(s) may be micro-scale models. According to another example embodiment, the physics-based model(s) may be multi-scalar and/or multi-physics models of, e.g., brain tissues.

At the output step 130, the physics-based model(s) of the step 120 may be used to predict composite/tissue/material property(ies), such as properties to help gauge composite/tissue/material response and/or characterization, and may include, e.g., mechanical (e.g., stress) and/or electrical (e.g., potential) metrics versus applied strain plots, etc.

In an example embodiment, the physics-based multi-modal forward process 100 may be used to obtain composite response and/or characterization data.

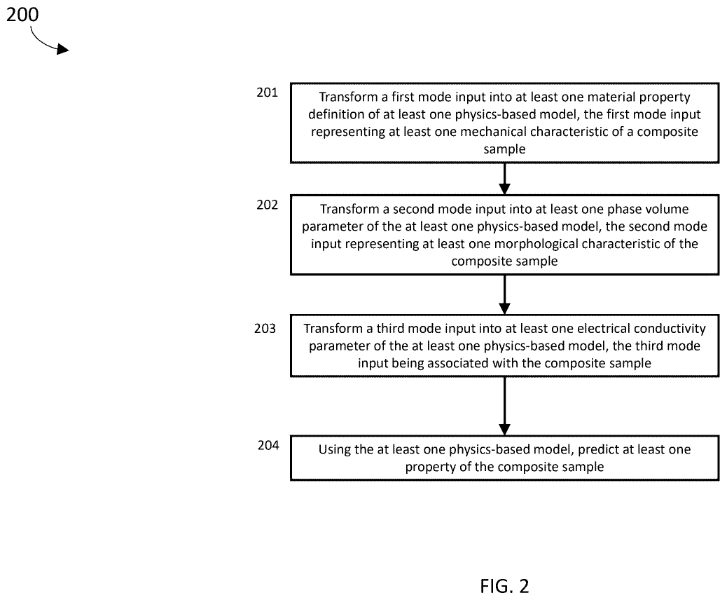

FIG. 2 is a flowchart of a method 200 for physics-based multi-modal prediction of composite properties, according to an example embodiment. The method 200 is computer-implemented and may be implemented using any computing device, e.g., a processor or combination of computing devices known to those of skill in the art.

The method 200 begins at step 201 by transforming a first mode input into at least one material property definition of at least one physics-based model. The first mode input represents at least one mechanical characteristic of a composite sample. At step 202, the method 200 transforms a second mode input into at least one phase volume parameter of the at least one physics-based model. The second mode input represents at least one morphological characteristic of the composite sample. The method 200 continues at step 203 by transforming a third mode input into at least one graph interconnect parameter of the at least one physics-based model. The third mode input represents at least one electrical characteristic of the composite sample. At step 204, using the at least one physics-based model, the method 200 then predicts at least one property of the composite sample.

In an example embodiment of the method 200, the composite sample may be a soft composite sample or a hard composite sample.

According to an example embodiment of the method 200, the at least one physics-based model may include at least one finite element (FE) model, and the predicting may include, via a FE solver, using the at least one FE model, predicting the at least one property.

In an example embodiment of the method 200, the predicted at least one property of the composite sample may include at least one of a mechanical property, an electrical property, and a biochemical property.

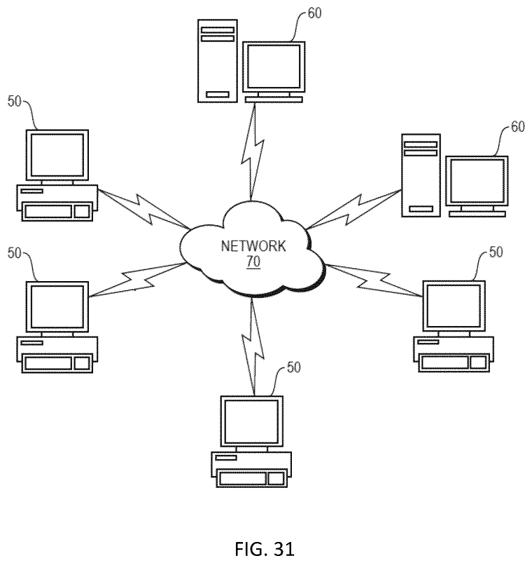

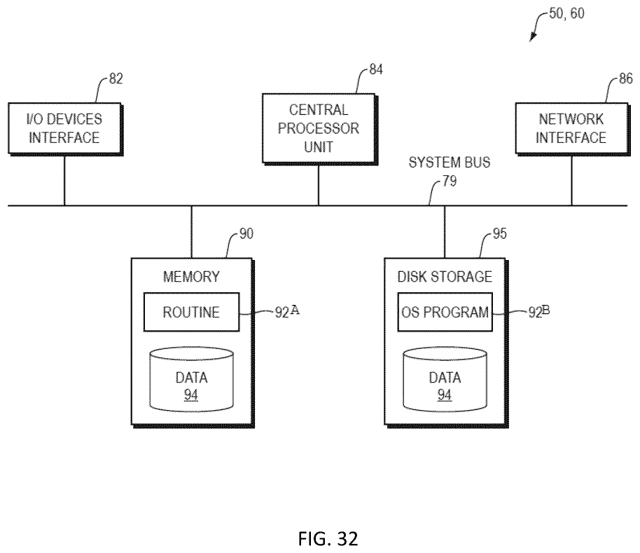

As noted above, the method 200 is computer implemented and, as such, the functionality and effective operations, e.g., the transforming (201, 202, and 203) and predicting (204), are automatically implemented by one or more digital processors. Moreover, the method 200 can be implemented using any computer device or combination of computing devices known in the art. Among other examples, the method 200 can be implemented using computer(s)/device(s) 50 and/or 60 described hereinbelow in relation to FIGS. 31 and 32.

Example Physics-Based Multi-Modal Forward Process with Generative ML/AI

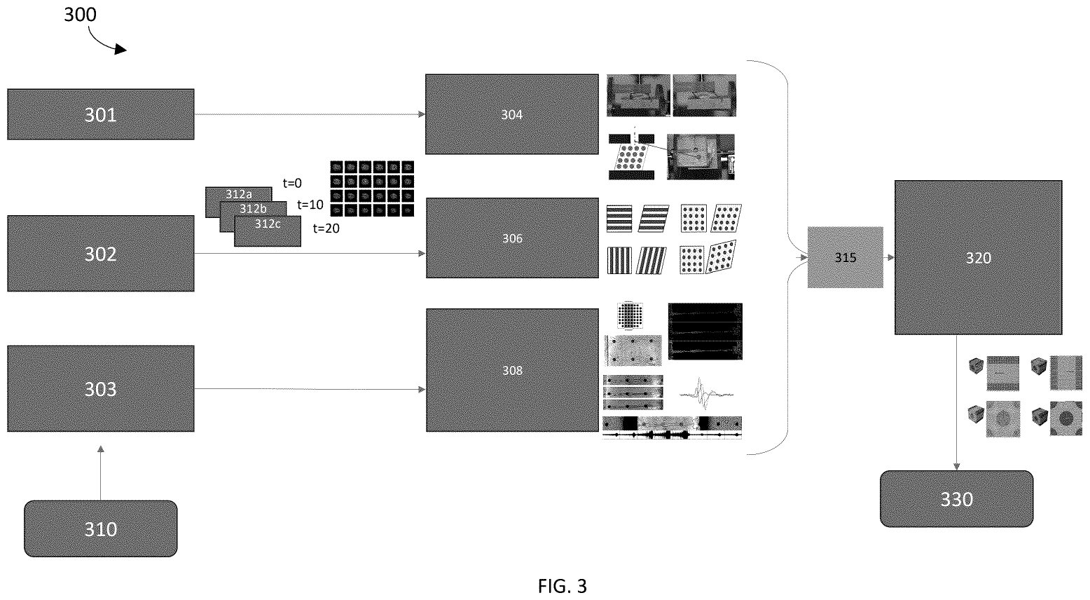

FIG. 3 is a flow diagram of a physics-based multi-modal forward and generative ML/AI process 300, according to an example embodiment. The process 300 may include input step 310, generative ML/AI (gen AI) step 315, physics-based modeling step 320, and output step 330. In an example embodiment, the process 300 may be a pure physics-based multi-modal FEM solution with generative ML/AI capabilities.

At input step 310, mechanical data 301, morphology data 302, and electrical data 303 may be obtained for a composite sample (not shown).

The mechanical data 301 may include, e.g., strain, load (shear, tension, compression, etc.), and other test setup data. In an example embodiment, the data 301 may be used to generate or configure material property definition(s) 304 for physics-based model(s), e.g., FE model(s) or RVE(s). According to another example embodiment, generating the definition(s) 304 may include converting the data 301 to an array format, such as the NumPy format or other suitable format known to those of skill in the art. The array format conversion may be performed via Excel or other suitable known tool. Examples of mechanical data are further described in Agarwal, M., et al., “Data-Driven Depiction of Aging Related Physiological Volume Shrinkage in Brain White Matter: An Image Processing Based Three-Dimensional Micromechanical Model,” Journal of Engineering and Science in Medical Diagnostics and Therapy 8, No. 4 (2025), which is herein incorporated by reference in its entirety.

The morphology data 302 may include, e.g., MRE/MRI scans (e.g., brain scans) or SEM image data. In an example embodiment, the data 302 may be, e.g., DTI scans 312a, 312b, and 312c at timesteps of t=0, t=10, and t=20, respectively. According to another example embodiment, the data 302 may be used to control or configure phase volume parameter(s) 306 for physics-based model(s), e.g., FE model(s). For instance, in yet another example embodiment, morphology data 302, e.g., image data, may be converted into a 3D array (i.e., voxel) format, such as the NumPy format or other suitable format known to those of skill in the art.

The electrical data 303 may be, e.g., conduction and/or neuro-pulse data, and/or may include, e.g., drug/pigment induced neuron excited pulse transmission experimental data. According to an example embodiment, the data 303 may be used to configure or define graph interconnect parameter(s) 308 for physics-based model(s), e.g., FE model(s). For instance, in another example embodiment, the data 303 may include pulse transmission signals that help to achieve an understanding of, e.g., interconnects between neurons, i.e., by graphing neuron networks based on pulse excitation.

It should be noted that, according to an example embodiment, the input types 301, 302, and/or 303 can be GUI or equation scripted inputs defined in a physics-based modeling tool, e.g., a FEM tool such as Abaqus, COMSOL, or Ansys for the physics-based forward and generative AI process 300 shown in FIG. 3. Similarly, in another example embodiment, the input types 301, 302, and/or 303 can be coded (e.g., via Python or other suitable known tool) into a physics-based modeling tool, e.g., a FEM tool such as Abaqus and used in a ML model input layer, e.g., as part of the hybrid process 400 described in more detail hereinbelow in relation to FIG. 4. Examples of scripted electrical data (e.g., the input type 303) are further described hereinbelow and in Appendix A.

To continue, gen AI step 315 may employ a module to apply one or more generative ML/AI technique(s). In an embodiment, the generative ML/AI technique(s) may include powerful techniques for synthesizing parameter combinations within a universe of possible combinations as defined by one or more user criteria. According to another embodiment, gen AI step 315 may include generating one or more RVE/REV/RUC/RUV/etc. combinations using generative ML/AI technique(s). In an embodiment, generative ML/AI models and frameworks employed at gen AI step 315 may include RAG and GANs, for non-limiting examples; other known generative ML/AI models and frameworks are also suitable. Using such generative ML/AI models and frameworks at gen AI step 315 can enable generating numerous additional combinations of RVEs for the forward workflow 300. As an illustrative example, if constraints are defined for the mechanical data modality 301—for instance, setting limits on possible shear/tensile/compression load, boundary condition(s) (B.C.(s)), and/or stress values—gen AI step 315 can generate any number of additional combinations of the data modalities 301, 302, and/or 303 to allow more options for model training, such as at step 320.

The process 300 has numerous advantages. For instance, the process 300 allows for generating large quantities of training data (including both positive and negative training examples) for an example system of embodiments to enable more efficient training and mitigate model overfitting problems due to a limited data set and/or an excessively skewed dataset. Hence, in addition to the process 100 (described hereinabove with respect to FIG. 1), the process 300 allows users to leverage generative ML/AI techniques to build physics-based model geometries, e.g., REVs/RVEs/RUCs/RUVs/etc., for solving user FE codes.

At physics-based modeling step 320, the material property definition(s) 304, the phase volume parameter(s) 306, and the graph interconnect parameter(s) 308 may be used to build or construct physics-based model(s), e.g., FE model(s). In an example embodiment, the physics-based model(s) may be micro-scale models. According to another example embodiment, the physics-based model(s) may be multi-scalar and/or multi-physics models of, e.g., brain tissues.

At output step 330, the physics-based model(s) of step 320 may be used to predict composite/tissue/material property(ies), such as properties to help gauge composite/tissue/material response and/or characterization, and may include, e.g., mechanical (e.g., stress) and/or electrical (e.g., potential) metrics versus applied strain plots, etc.

In an example embodiment, the physics-based multi-modal forward process 300 may be used to obtain composite response and/or characterization data.

Example Creation of Realistic RVEs with Generative ML/AI

In an embodiment, generative ML/AI model(s) may be leveraged at output step 130 of the forward process 100 (FIG. 1) to enhance generated RVEs, e.g., micro-scale physics-based models, of composite samples by providing the RVEs with realistic, e.g., human-mimicking, traits. For example, by feeding high-resolution images included in the morphology data 102 (FIG. 1) and other input data types included in the electrical data 103 (FIG. 1) to generative ML/AI model(s), any number of possible combinations of RVEs, e.g., micro-architectures, can be produced, while remaining within the bounds of having realistic features. As a further example, generative ML/AI model(s) may be employed to add connections (e.g., tissue tethering) and/or elements (e.g., tissue degradation and damage modeling) to RVEs of composite samples. In an embodiment, generative ML/AI model(s) may include variational autoencoders (VAEs), diffusion models, transformer models, and recurrent neural networks (RNNs) (such as a long short-term memory (LSTM)), for non-limiting examples. According to another embodiment, generative ML/AI model(s) may be applied to the workflow 100 to enhance RVE, e.g., micro-scale model, complexity and fidelity to a real-world micro-architecture depiction of a composite sample.

### Example User Experience-Driven Workflow for RVE Selection

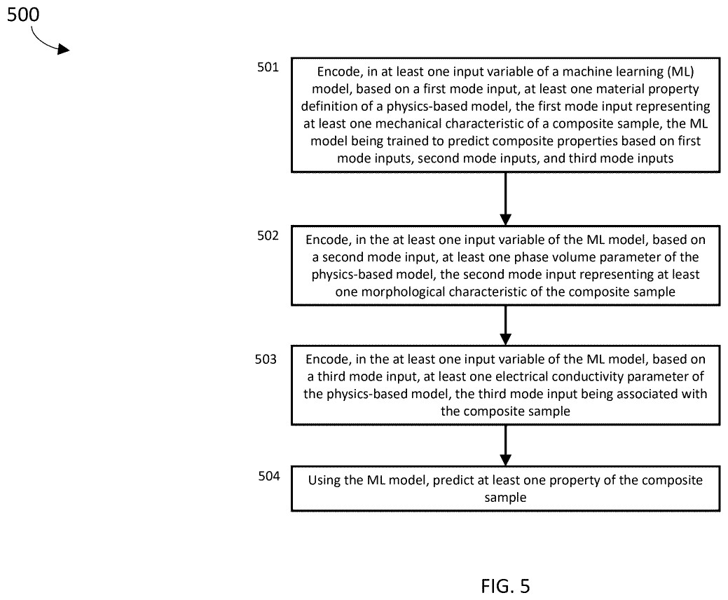

In an embodiment, a process of using generative ML/AI model(s) to generate and retain RVEs, e.g., micro-scale models, with enhanced realism, such as the process described hereinabove, may be carried out according to one of two example filtering approaches described below. The resulting enhanced RVEs may then be used for training an ML/AI model as part of a hybrid workflow, e.g., the workflow 400 of FIG. 4 (described hereinbelow), or as part of an embodiment of the method 500 of FIG. 5 (described hereinbelow) that includes training an ML/AI model.
a) Application Filtering Approach: In this approach, the resulting enhanced RVEs may be used as-is for training an ML/AI model as described above.
b) User Input Filtering Approach: In this approach, which may be performed as part of a workflow (e.g., 400 or 500), “gate checks” may be conducted for the resulting enhanced RVEs whereby it is determined whether a given RVE is realistic (true positive) or not (false positive) based on user input. The RVEs that successfully pass their gate checks (i.e., true positives) may then be used for training an ML/AI model as described above.

According to another embodiment, to further improve accuracy in generating realistic RVEs, e.g., micro-scale models or micro-architectures, a framework that combines ML/AI model(s) with knowledge bases may be utilized. Such a framework may include employing a RAG technique in combination with GAN model(s), for non-limiting example.

In an embodiment, an application programming interface (API) may be provided for visualizing enhanced RVEs, e.g., at output step 130 of the forward process 100, to enable either of the above example filtering approaches (application or user input) to be used for training and/or testing as part of a multi-modal hybrid model stage of a workflow, e.g., 400 or 500.

### Example Hybrid (ML/AI and Physics-Based) Multi-Modal Forward Process

FIG. 4 is a flow diagram of a hybrid multi-modal forward process 400, according to an example embodiment. The process 400 may include input step 410, ML/AI modeling step 440, prediction step 420, and output step 430.

The process 400 may be a hybrid model variant of a multi-modal solution. For instance, the process 400 may be a hybrid ML/AI and physics-based method.

Input step 410 may include obtaining multi-modal or heterogenous data inputs for a composite sample (not shown), as in input step 110 (FIG. 1) of the physics-based process 100 (FIG. 1) or input step 310 (FIG. 3) of the physics-based generative ML/AI process 300 (FIG. 3). In an example embodiment, the data inputs may be converted or encoded into an array format, such as via the NumPy library or other suitable library known to those of skill in the art. According to another example embodiment, after generating arrays using the data inputs from the step 410, the arrays can be directly fed into ML/AI modeling step 440. This may parallel the approach of the physics-based process 100 with respect to physics-based modeling step 120 (FIG. 1) or the approach of the physics-based generative ML/AI process 300 with respect to physics-based modeling step 320 (FIG. 3).

At ML/AI modeling step 440, the multi-modal data obtained from input step 410 may be fed to an ML/AI model, e.g., a neural network, instead of, e.g., solving FE model using a FE solver as in the physics-based process 100 or the physics-based generative ML/AI process 300. In an example embodiment, using an ML/AI model in step 440 may be faster than a physics-based solver. It should be noted that embodiments are not limited to neural networks; rather, any suitable known ML/AI model, such as decision trees and random forests, among other examples, may be used.

In an example embodiment, prediction step 420 may generate predictions of composite (e.g., tissue) properties, e.g., mechanical and/or electrical properties at a micro-mechanical scale.

According to an example embodiment, data generated at output step 430 may help gauge composite/tissue/material response and/or characterization, and may include, e.g., mechanical (e.g., stress) and/or electrical (e.g., potential) metrics versus applied strain plots, etc.

In another example embodiment, the hybrid multi-modal forward process 400 may be used to obtain composite response and/or characterization data.

It should be noted that a hybrid modeling approach of embodiments, e.g., the process 400, may be provided as a further alternative for producing a forward process solution using FE codes and generating an output, e.g., 430. A physics-based solving methodology of embodiments, e.g., the process 100 or 300, may also be used, e.g., to generate an output 130 or 330, respectively.

FIG. 5 is a flowchart of a method 500 for hybrid multi-modal prediction of composite properties, according to an example embodiment. The method 500 is computer-implemented and may be implemented using any computing device, e.g., a processor or combination of computing devices known to those of skill in the art.

The method 500 begins at step 501 by encoding, in at least one input variable of a ML model, based on a first mode input, at least one material property definition. The first mode input represents at least one mechanical characteristic of a composite sample. The ML model is trained to predict composite properties based on first mode inputs, second mode inputs, and third mode inputs. At step 502, the method 500 encodes, in the at least one input variable of the ML model, based on a second mode input, at least one phase volume parameter. The second mode input represents at least one morphological characteristic of the composite sample. The method 500 continues at step 503 by encoding, in the at least one input variable of the ML model, based on a third mode input, at least one electrical conductivity parameter. The third mode input is associated with the composite sample. At step 504, using the ML model, the method 500 then predicts at least one property of the composite sample.

As noted above, the method 500 is computer implemented and, as such, the functionality and effective operations, e.g., the encoding (501, 502, and 503) and predicting (504), are automatically implemented by one or more digital processors. Moreover, the method 500 can be implemented using any computer device or combination of computing devices known in the art. Among other examples, the method 500 can be implemented using computer(s)/device(s) 50 and/or 60 described hereinbelow in relation to FIGS. 31 and 32.

In an example embodiment, the method 500 may further include training the ML model based on multiple training data tuples. Each of the multiple training data tuples may include (i) a first mode training input, (ii) a second mode training input, (iii) a third mode training input, and (iv) at least one training property. According to another example embodiment, the method 500 may further include generating at least one training property of a given training data tuple of the multiple training data tuples. The generating may include transforming the first mode training input of the given training data tuple into at least one material property definition of at least one physics-based model. The first mode training input may represent at least one mechanical characteristic of a composite training sample. The generating may further include transforming the second mode training input of the given training data tuple into at least one phase volume parameter of the at least one physics-based model. The second mode training input may represent at least one morphological characteristic of the composite training sample. The generating may further include transforming the third mode training input of the given training data tuple into at least one electrical conductivity parameter of the at least one physics-based model. The third mode training input may be associated with the composite training sample. The generating may further include, using the at least one physics-based model, predicting the at least one training property of the given training data tuple.

According to an example embodiment of the method 500, the predicted at least one property may include at least one micro-scale property. The method 500 may further include, using at least one homogenization model, transforming the at least one micro-scale property into at least one macro-scale property of the composite sample. In another example embodiment of the method 500, the at least one homogenization model may include a FFT model.

In an example embodiment, the method 500 may further include, using an optimization model, constructing a design space based on the predicted at least one property. According to another example embodiment, the method 500 may further include, based on the constructed design space, synthesizing a real-world composite material. In yet another example embodiment, the method 500 may further include comparing the synthesized real-world composite material and the composite sample and, based on a result of the comparing, modifying at least one of the first mode input, the second mode input, and the third mode input. According to an example embodiment of the method 500, the synthesized real-world composite material may be a brain-like tissue. In another example embodiment of the method 500, the optimization model may include at least one of: a genetic model, a grid search model, a space-filling model, a particle swarm model, another multi-objective optimization model, and a generative ML/AI model.

According to an example embodiment of the method 500, the ML model may be a neural network model, a decision tree model, or a random forest model. In another example embodiment of the method 500, the at least one input variable may include an input layer of the neural network model.

In an example embodiment of the method 500, the composite sample may be a human brain tissue sample or an animal brain tissue sample.

According to an example embodiment, the method 500 may further include encoding, in the at least one input variable of the ML model, based on a fourth mode input, at least one additional parameter. The fourth mode input may include at least one of: a biochemical data input, a LLM based input, a NLP based input, a time series input, a sensor input, an equation based input, a video input, a radiation data input, and a patient history input. The ML model may be further trained to predict composite properties based on fourth mode inputs.

In an example embodiment of the method 500, the second mode input may include at least one of: MRE data, MRI data, DTI data, SEM data, and CT data.

According to an example embodiment of the method 500, the third mode input may include (i) at least one graph interconnect characteristic of the composite sample or (ii) a growth model corresponding to the composite sample. In another example embodiment, the method 500 may further include configuring at least one of: (i) a graph branch length parameter, (ii) a branching proliferation criterion, (iii) a branching expansion criterion, and (iv) an interaction parameter, for the growth model.

Solving physics-based models using tools like Ansys, Abaqus, and NX®, etc. may be time-consuming and/or computationally expensive. Accordingly, embodiments may leverage ML/deep learning techniques (e.g., neural networks) to predict composite (e.g., tissue) properties response. The hybrid multi-modal forward process 400 (FIG. 4) and the method 500 may be examples of such an approach. An example embodiment that leverages ML/deep learning techniques may utilize multi-modal data inputs converted into array format (e.g., NumPy arrays) such as described hereinabove with respect to step 410 (FIG. 4) of the hybrid process 400.

It is noted that a hybrid framework of embodiments, such as the process 400 or the method 500, is a further way to quickly solve a multi-modal composite (e.g., tissue) modeling problem using a data-driven approach instead of physics-based techniques.

By leveraging LLMs and/or NLP techniques, embodiments can incorporate additional modalities and/or further heterogeneity in data types, such as at the input step 110 (FIG. 1), 310 (FIG. 3), or 410 (FIG. 4). For instance, according to an example embodiment, another input to a workflow (e.g., the process 100 of FIG. 1, the method 200 of FIG. 2, the process 300 of FIG. 3, the process 400 of FIG. 4, or the method 500 of FIG. 5) may be a patient history record, including, for instance, blood levels/blood pressure, disease (e.g., diabetes) history, cognitive scale data, and/or accident history, etc., to determine more reliable composite/material properties. According to another example embodiment, such a further input modality can be encoded as arrays (e.g., numerical or categorical data) in a workflow input stage, such as the input step 410.

In an example embodiment, a further dimension for a multi-modal workflow may be time series data. For instance, tissue data recorded from a sensor, e.g., a sweat sensor, attached to a subject's skin or skull may be used in the case of tissues. As another example, sensor data obtained from non-linear composites structures, e.g., hard polymers, may be used. Yet another instance of capturing time series data may include using video files over MRE/MRI images. In an example embodiment, instead of MRE/MRI images, an input modality may be video of the scans, e.g., CT scans, taken for a certain duration and at certain intervals to encode composite/material change and/or response over time using MRE/MRI equipment.

According to an example embodiment, radiation data may also be analyzed as yet another input modality. For instance, according to another example embodiment, during space travel, radiation may affect, e.g., astronauts' bone and/or heart function. Many other instances exist of professions that are risky and constantly under high radiation exposure. As just one example, telecom industry workers have their bodies exposed to electromagnetic (EM) waves and EM radiation (EMR) on a very frequent basis. This puts them at greater risk of tissue damage and/or atrophy. Embodiments may be used to model the health effects of occupational radiation exposure.

In an example embodiment, a further heterogenous data type may include biochemical data. For instance, certain ions and/or molecules may be released and/or degrade with age in original brain matter or other soft tissue composition. In another example embodiment, having biochemistry measurements (e.g., time series data) of such varying levels of protein/fat/ions/etc. can further enhance modeling of aging soft tissues.

Embodiments can also employ equation-driven multi-modal input, in addition to, e.g., raw experimental data, such as mechanical data, morphology data, and/or electrical data. In an example embodiment, an input variable of a ML model (e.g., an input layer of a neural network) may have such equation-driven parameter(s) encoded as parametric function(s) in, e.g., Abaqus distributed user material (UMAT) or vectorized user material (VUMAT) format. Other known formats are also suitable. To continue, according to another example embodiment, a parametric function for an equation-driven parameter may be coded in Fortran or other suitable known machine compiler to generalize a workflow for any composite/material under any loading and/or surrounding conditions.

Examples of hybrid simulation techniques are further described in Appendix A to U.S. Provisional Application No. 63/647,998 (Provisional Appendix A), which is herein incorporated by reference in its entirety. Provisional Appendix A describes, among other things, a hybrid computational workflow to analyze BWM RVEs, defined to incorporate varying microarchitectures, material properties, and interactions. The RVEs are used to train ML/deep learning (DL) neural networks, which act as surrogates to FEM models. BWM microarchitecture information encoded in a voxelized location is then used as input data and is consequently incorporated into deep 3D convolution neural network models that cross-reference the RVEs' stress tensor and stiffness/material properties matrix (output data). In turn, this output data is calculated in parallel using a custom 3D FEM framework. This novel combination of DL and FEM results in a hybrid computational workflow to compute a degree of Poynting effect, with significantly lower computational costs, as well as greater case of parameterization and multi-scalability, when compared to pure FEMs,

### Example Morphology Data

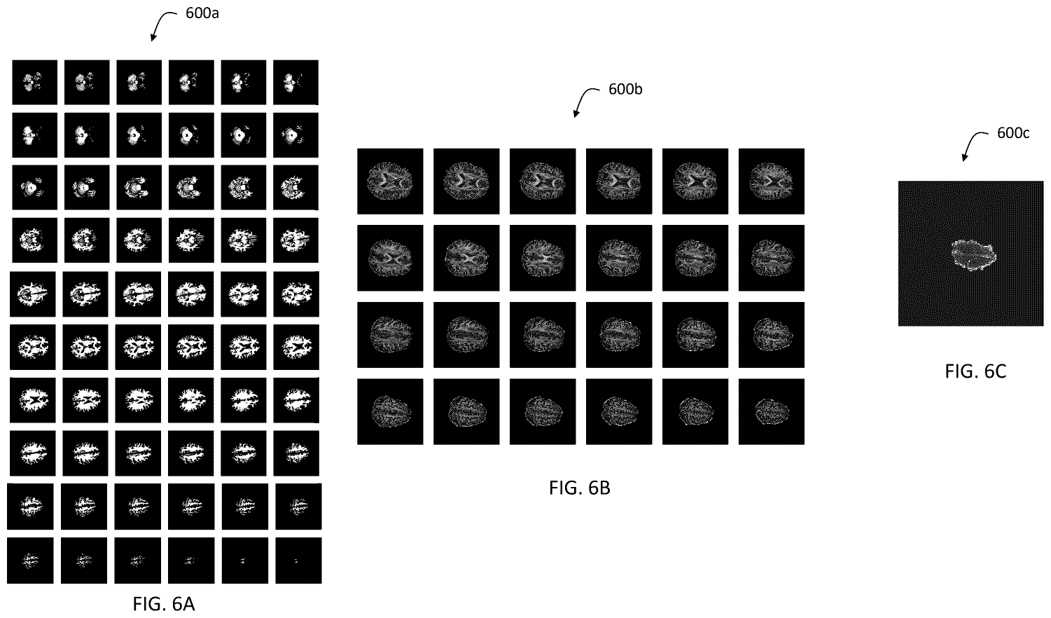

FIG. 6A is representative MRI images 600a, e.g., functional MRI (fMRI) images, from a test subject, according to an example embodiment. The MRI images 600a include 60 scans/slices of 120×120 resolution obtained to image the whole brain for the test subject. Scans may be taken in an AP (Anterior-Posterior) and LR (Left to Right) direction. In MRE/MRI experiments, four repeated AP and LR-excitations may be performed. After image analysis, derived variables such as displacement (3D vector field), non-linear inversion (NLI)-MRE (classic), and WM/grey matter (GM) masks datasets for some processed images may be obtained to aid in further imaging processing.

In an example embodiment, MRI files containing the sample images 600a may be stored in, e.g., the Neuroimaging Informatics Technology Initiative (NIfTI) format, and may later be processed using Python libraries/interfaces (e.g., NiBabel).

MRI can differentiate between WM and GM and can also be used to diagnose aneurysms and tumors. MRI images for, e.g., fMRI, may be stored using the NIfTI format. This is a very simple format that may result in a single file with extension “.nii”. If a NIfTI file is compressed using, e.g., the gzip tool, the file will end with “.nii.gz” instead; other known compression tools are also suitable. It is further noted that embodiments are not limited to any particular storage format. Rather, any suitable format known in the art may be used.

The NiBabel and SimpleITK interfaces (the latter providing a simplified interface to the Insight Segmentation and Registration Toolkit (ITK)) are in wide use for advanced medical imaging processing for AI/ML development. NiBabel offers high-level format-independent access to neuroimages, as well as an API with various levels of format-specific access to all available information in a particular file format. SimpleITK is good for processing, segmentation, and registration of scientific images in two, three, or more dimensions.

NIfTI is adapted from the widely used Analyze™ file format and uses “empty space” in an Analyze header to add several new features. Thus, older non-NIfTI-aware software that uses the Analyze format may still be compatible with NIfTI.

FIG. 6B is representative DTI images 600b from the test subject of FIG. 6A, according to an example embodiment. The images 600b may be useful to understand integrity and/or connectivity in BWM. In an example embodiment, the DTI images 600b may provide information regarding structural orientation.

FIG. 6C is a sample masked image 600c for FA measurement in DTI from the test subject of FIG. 6A, according to an example embodiment.

The images 600a, 600b, and 600c illustrate examples of morphology data using MRE/MRI images to determine brain matter VF. In addition, the sample images 600a, 600b, and 600c showcase that integrating components from medical imaging technologies can be leveraged to formulate composite (e.g., brain tissue) model geometry in the multi-scale, multi-physics solutions of embodiments. The sample images 600a, 600b, and 600c also demonstrate how MRE/MRI images can be used in a physics-based model workflow, e.g., as inputs 102 to the process 100 (FIG. 1) or inputs 302 to the process 300 (FIG. 3), to define interphasic volume fractions. Examples of morphology data are further shown and described in Agarwal, M., et al., “Data-Driven Depiction of Aging Related Physiological Volume Shrinkage in Brain White Matter: An Image Processing Based Three-Dimensional Micromechanical Model,” Journal of Engineering and Science in Medical Diagnostics and Therapy 8, No. 4 (2025), which is herein incorporated by reference in its entirety.

### Example Scalability/Homogenization Process

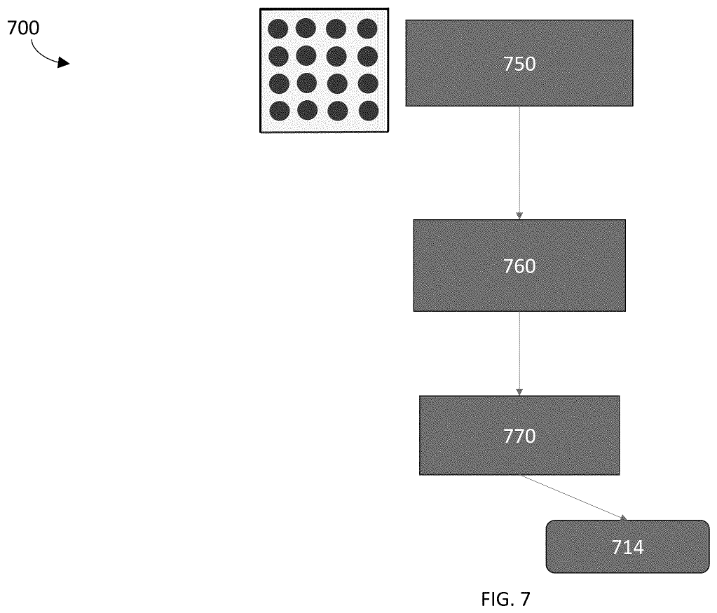

FIG. 7 is a flow diagram of a scalability/homogenization process 700, according to an example embodiment. The process 700 includes input step 750, homogenization step 760, and prediction step 770.

Input step 750 may utilize FE-scale outputs—e.g., anisotropic composite properties from micro-mechanical models—which may be obtained from the physics-based process 100 (FIG. 1), the physics-based method 200 (FIG. 2), the physics-based generative ML/AI process 300 (FIG. 3), the hybrid process 400 (FIG. 4), or the hybrid method 500 (FIG. 5).

Homogenization step 760 may include applying homogenization techniques to get macro-scale properties from micro-scale results of input step 750. For instance, according to an example embodiment, FFTs and/or other suitable known homogenization models may be used.

Prediction step 770 may include predicting homogenized composite (e.g., tissue) properties at macro-scale.

An output 714 obtained via the process 700 may reflect a multi-modal, multi-scale, and multi-physics forward model (e.g., a brain model) to predict composite (e.g., tissue) properties.

In addition, the process 700 may be an example of using anisotropic model output results from nano-/micro-/meso-scales and homogenizing the results to obtain continuum level (i.e., macro-scale) properties.

### Example Inverse Process

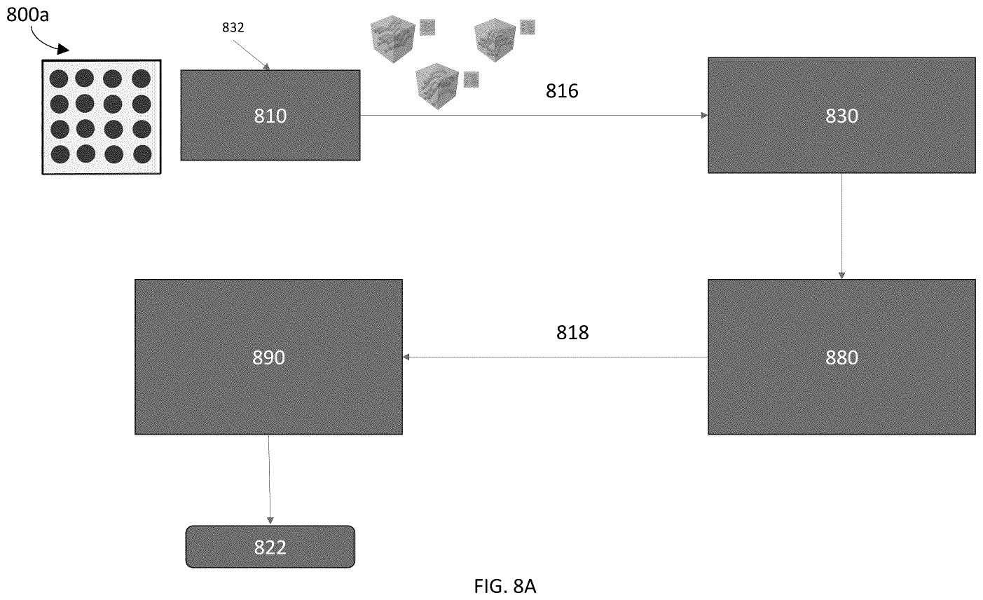

FIG. 8A is a flow diagram of an inverse process 800a, according to an example embodiment. The process 800a includes input step 810, forwarding modeling pass 816, prediction step 830, design step 880, inverse modeling pass 818, and engineering step 890.

At input step 810, multi-modal data inputs 832 may be obtained for a composite sample, e.g., brain tissue. In an example embodiment, the inputs 832 may be used to configure definition(s) and/or parameter(s) of a physics-based model, e.g., by constructing composite RVE(s). Alternatively, in another example embodiment, the inputs 832 may be used to encode input variable(s) of an ML/AI model.

In an example embodiment, at forward modeling step 816, a physics-based model configured at step 810 may be used in a physics-based forward modeling step, e.g., the physics-based modeling step 120 (FIG. 1) or 320 (FIG. 3). Alternatively, in another example embodiment, an ML/AI model with input variable(s) encoded at step 810 may be used in ML/AI forward modeling step, e.g., ML/AI modeling step 440 (FIG. 4).

According to an example embodiment, prediction step 830 may output predicted properties for a composite sample, such as a range of mechanical properties (e.g., stress), a range of electric potential, etc., similar to output step 130 (FIG. 1), 330 (FIG. 3), or 430 (FIG. 4).

In an example embodiment, design step 880 may include, based on predicted properties of step 830, formulating or constructing a hypothetical design space for newly synthesized composites/materials/tissues with ranges of values for different properties or characteristics, such as stress, potential, and/or stiffness, etc., among other examples.

According to an example embodiment, inverse modeling pass 818 may leverage any suitable known optimization techniques, ML/AI model (such as genetic models), grid search techniques, space-filling models, and/or particle swarm optimization, as well as other multi-objective optimization models, etc., to identify potential configurations or permutations of properties by exploring a design space constructed in step 880. In another embodiment, the inverse pass 818 may utilize any suitable known generative ML/AI technique(s) or model(s) for optimization and/or to generate potential configurations in the design space of inverse modeling pass 818. For instance, generative ML/AI technique(s) or model(s) may be employed as another avenue to optimize parameter spaces for physics-based models in the inverse workflow 800a. According to an embodiment, generative ML/AI technique(s) or model(s) may also be leveraged to help reduce a search space faster to identify the best possible combinations for engineering tissues and/or material recommendations, as well as to obtain engineered meta-materials including non-linear and/or linear composites.

In an example embodiment, engineering step 890 may include, based on potential configurations or permutations identified in step 818, synthesizing or engineering composites (e.g., tissues) by specifying parameters such as VFs, geometry (morphology), graph interconnects (e.g., neuronal interconnects), etc.

With a resulting output 822 of the inverse process 800a, in an example embodiment, it may be possible to engineer multi-scale materials, such as by leveraging outputs of the multi-modal forward model step 816 into inverse design step 880.

According to an example embodiment, the inverse process 800a may include leveraging state of the art optimization techniques and/or ML/AI models at step 818 to fit parameters predicted at step 830 via the forwarding modeling pass 816 to engineer or synthesize new composites/materials/meta-materials (e.g., tissues) with desired properties—e.g., to conduct material discovery—via steps 880 and 890.

Example Inverse Process Design and/or Execution Using Generative ML/AI

In an embodiment, in addition to or as an alternative to using optimization techniques and/or ML/AI models (e.g., genetic algorithms and/or grid search techniques), generative ML/AI models may be used at inverse modeling pass 818 of the inverse process 800a (FIG. 8A). For example, after the inverse workflow 800a establishes bounds for micro-scale physics model/micro-architecture parameters (e.g., RVE and/or geometry parameters) at step 880, generative ML/AI model(s) may be utilized or “sandwiched” with other ML/AI models and/or optimization techniques at inverse modeling pass 818 to generate a multitude of other micro-architecture combinations. In this way, numerous additional micro-architectures, e.g., RVEs, may be generated.

According to another embodiment, generative ML/AI model(s) may be leveraged in the workflow 800a as a relearning or repurposing/retraining component, for instance, after a first iteration of inverse flow results 822 are produced from an initial pass of the workflow 800a.

In an embodiment, generative ML/AI technique(s) may be utilized for transfer learning, i.e., using data and/or results obtained from performing one ML/AI task to improve performance in another ML/AI task. For example, generative ML/AI technique(s) may serve as a powerful tool in transferring knowledge of inverse workflows to generate RVEs for many other applications. Applications for soft tissues may include aging, TBIs, tissue damage, accidents, tissue degeneration, and many other types of pathologies, for non-limiting examples.

As discussed herein, an example inverse workflow of embodiments, e.g., 800a, can be leveraged for both soft and hard linear and non-linear composites and any known engineered material application types. While examples are provided herein directed to soft tissue modeling applications, it should be noted that embodiments are not limited to modeling soft tissues.

### Example Enhancement of Inverse Process Outputs Using Generative ML/AI

In an embodiment, suitable known generative ML/AI technique(s) can be leveraged to generate 3D models and/or videos (e.g., MRI/MRE video files) in conjunction with outputs of the process 800a (FIG. 8A). Examples of such generative ML/AI techniques may include the following:
a) Neural Radiance Fields (NeRFs): 3D object synthesis from 2D images.
b) Make-a-Video (Meta Platforms, Inc., Menlo Park, CA): AI-driven video synthesis from text.
c) DreamFusion (Google LLC, Mountain View, CA): Text-to-3D model generation.

According to another embodiment, generative ML/AI technique(s) and model(s) may be utilized for enhancing inverse workflow outputs, e.g., 822 (FIG. 8A). For example, an inverse workflow, e.g., 800a, may generate tissue structure designs at multiple regions of interest (ROIs). One or more generative ML/AI technique(s), e.g., NeRFs, may then be used to integrate and/or stitch together multiple ROIs of generated tissue tracts to create continuum scale brain models. In turn, this may enable generation of one-to-one scale models of macroscopic brains from multi-scalar multi-modal frameworks, thereby drastically improving computation capabilities to simulate brain response as well as to manufacture synthetic soft tissues that mimic real-world tissue behavior.

In an embodiment, text input type data, e.g., material properties and/or predicted mechanical characterization data, may be integrated to generated tissue tracts using generative ML/AI technique(s) or model(s) to depict, e.g., aging/trauma, related influence on final generated/recommended inverse flow designs produced by the workflow 800a.

According to another embodiment, generative ML/AI technique(s) or model(s) may also receive user-provided inputs, such as user prompts that specify oligodendrocyte or astrocyte connections.

### Example Generative ML/AI Techniques for Relearning/Retraining/Repurposing

In an embodiment, generative ML/AI techniques can be used for transfer learning/relearning, retraining, and model repurposing for other applications, in the context of inverse modeling. For example, a generative ML/AI component in inverse modeling may be employed as a relearning or repurposing/retraining tool, after one or more iterations of inverse workflow results, e.g., 822 (FIG. 8A), are produced by a first pass of an inverse process, e.g., 800a (FIG. 8A).

In an embodiment, generative ML/AI technique(s) may be utilized for transfer learning. For example, generative ML/AI technique(s) may serve as a powerful tool in transferring knowledge of inverse workflows to generate RVEs for many other applications. Applications for soft tissues may include aging, TBIs, tissue damage, accidents, tissue degeneration, and many other types of pathologies, for non-limiting examples.

As discussed herein, an example inverse workflow of embodiments with generative ML/AI techniques, e.g., 800b (described hereinbelow with respect to FIG. 8B), can be leveraged for both soft and hard linear and non-linear composites and any known engineered material application types. While examples are provided herein directed to soft tissue modeling applications, it should be noted that embodiments are not limited to modeling soft tissues.

FIG. 8B is a flow diagram of an inverse process 800b with generative ML/AI, according to an example embodiment. As shown in FIG. 8B, the process 800b may include gen AI step 815. In an embodiment, the process 800b may include accumulating and/or storing in memory results 822a-822n of multiple iterations of an inverse workflow, e.g., 800a (FIG. 8A), that does not use generative ML/AI. For instance, the results 822a-822n may be produced without using generative ML/AI functionality such as RAG and GANs. As another example, after N=10 iterations of a non-generative inverse workflow (such as 800a), e.g., 300, candidate designs 822a-822n may be produced.

Continuing with FIG. 8B, in an embodiment, gen AI step 815 may include processing the sample sets 822a-822n with one or more suitable known generative ML/AI technique(s). For instance, adversarial networks may be employed to filter the samples 822a-822n, for non-limiting example. According to another embodiment, gen AI step 815 optionally include receiving one or more user prompts 809. For example, a prompt 809 may be a text-based prompt such as: “Create another version of material type A (after non-generative inverse workflow execution), but now increase stiffness by 10%, Poisson's ratio by 5%, and failure load by 50%. Also, make sure new material designs are similar in material nature (constitutive behavior) to A.”

Continuing again with FIG. 8B, gen AI step 815 may then produce one or more optimized outputs 811a-811n. In an embodiment, the outputs 811a-811n may include material design generations. According to another embodiment, the outputs 811a-811n may in turn be used to create one or more final recommendations 813a-813n (constitutive components) for desired materials. In this way, the process 800b may enable using a workflow for one soft tissue for another tissue family.

### Example Electrical Data

In an embodiment, a third data modality of electrical data, e.g., inputs 103 to the process 100 (FIG. 1) or inputs 303 to the process 300 (FIG. 3), may include electrical signal data such as neurosignals, for non-limiting example.

Described hereinbelow are example feature engineering techniques that may be used to efficiently extract and/or feed electrical modality type data into a workflow of an embodiment, e.g., the process 100 or 300; other known feature engineering techniques are also suitable:
a) Continuous regressor inputs: In an embodiment, this technique may utilize any or all available signal inputs. According to another embodiment, a baseline approach may be employed whereby electrical modality data is treated as continuous incoming data and processed accordingly.
b) Signal segmentation code generation: In an embodiment, this technique may employ a categorical approach. According to another embodiment, neuro pulse signal potentials may be combined into sub-classes and/or ranges and then fed into an input channel, e.g., 103 or 303. In this way, computational costs may be reduced.
c) Signal clustering: In an embodiment, this technique may employ unsupervised methods to cluster signal potential into major groups and retain only a major cluster of signals. For example, according to another embodiment, k-nearest neighbors (KNN) methods can be used to assign weights to certain signal pulse/voltage value ranges (e.g., high, medium, and low), followed by grouping continuous signals into clusters. In an embodiment, the most predominant signal amplitude may be selected for use as input.

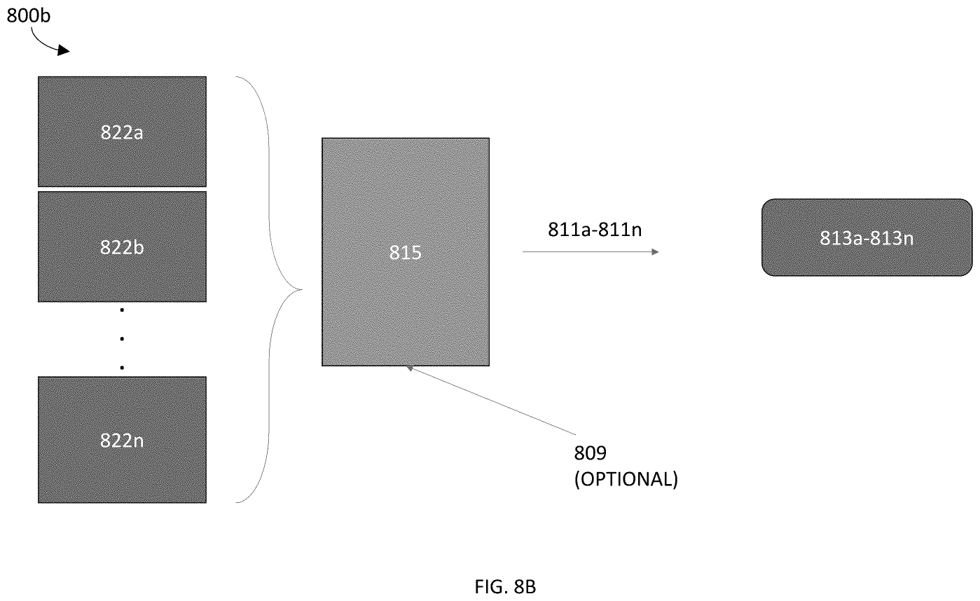

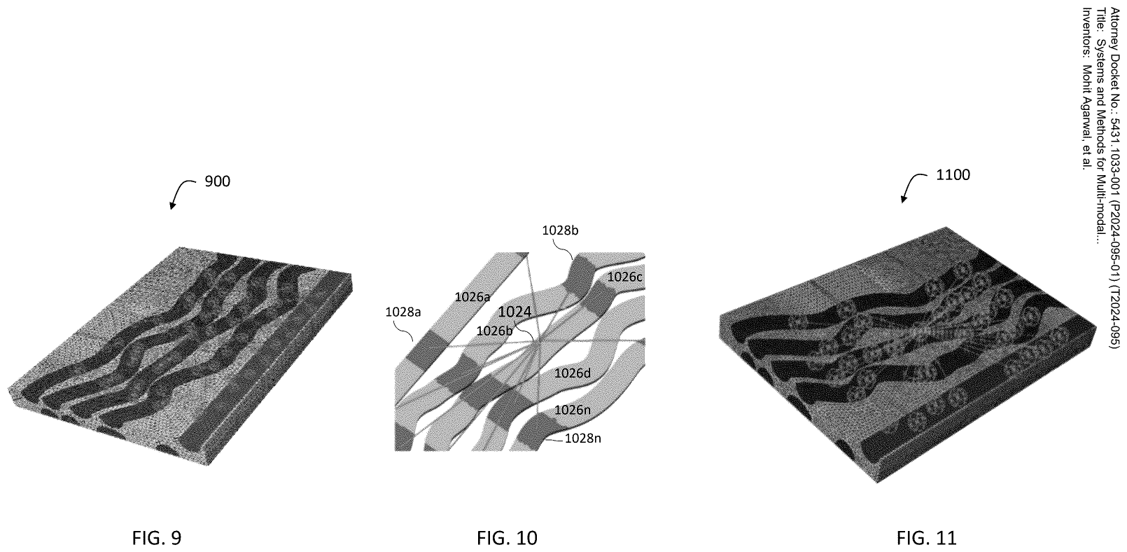

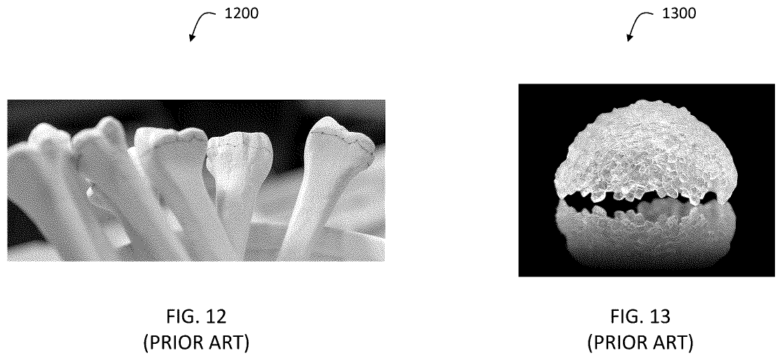

FIG. 9 is an image 900 of oligodendrocytes arbitrarily tethered to axons, according to an example embodiment. FIG. 10 is a schematic representation of an oligodendrocyte 1024 tethering to axons 1026a-1026n at different locations 1028a-1028n via myelin sheaths, according to an example embodiment. FIG. 11 is an image 1100 of a single oligodendrocyte tethering to surrounding axons, according to an example embodiment.

FIGS. 9-11 show examples of interconnects between phases, e.g., neuronal linkages, which can be defined in a physics-based model, such as via the interconnect parameter(s) 108 (FIG. 1) for the physics-based modeling step 120 (FIG. 1) or the interconnect parameter(s) 308 (FIG. 3) for the physics-based modeling step 320 (FIG. 3). Embodiments may leverage graph theory concepts to construct a web for electrical signal input, e.g., the input 103 (FIG. 1) or 303 (FIG. 3), in a forward workflow—either physics-based, e.g., the process 100 (FIG. 1), the method 200 (FIG. 2), or the process 300 (FIG. 3), or hybrid, e.g., the process 400 (FIG. 3) or the method 500 (FIG. 5).

For the process 400 or the method 500, according to an example embodiment, interconnect information may be encoded as a graph network in an ML/AI input variable to describe connected nodes.

### Example Synthesized/Tangible Products

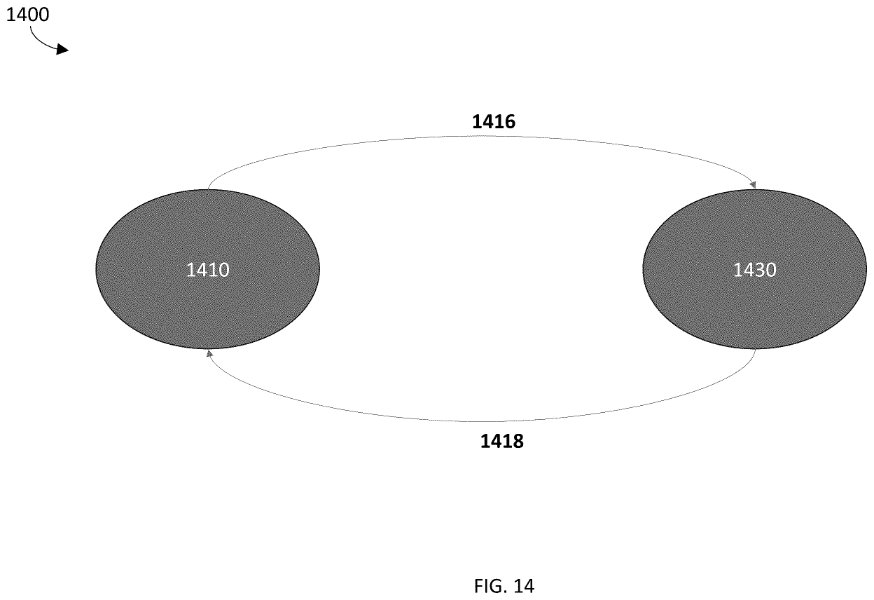

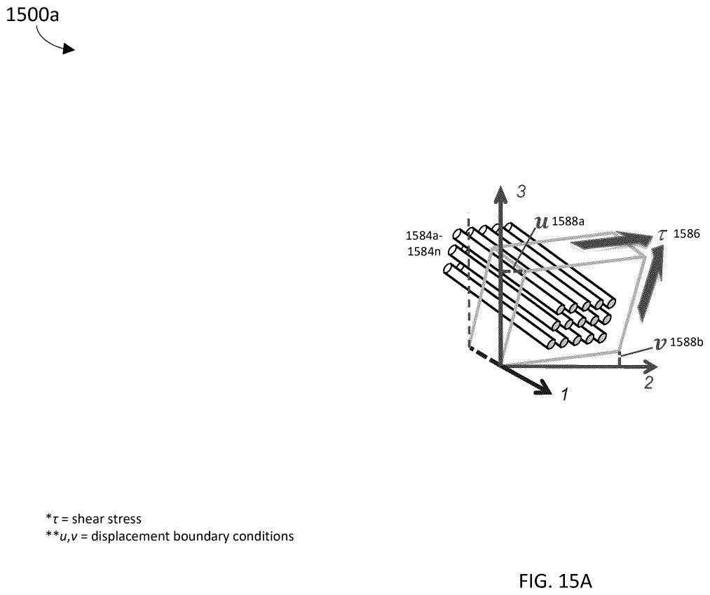

FIG. 12 is an image 1200 of prior art sawbones. FIG. 13 is an image 1300 of prior art synthesized brain-like tissues.

With the ability to reverse engineer composite design, embodiments can solve, among other things, the decades-old issue of a dearth of brain samples (as an example of composites or tissues) for experimental studies by engineering synthesis of bio-tissues. Such bioengineered tissue can be used in a similar way to how sawbones (e.g., the prior art sawbones of FIG. 12) are used in the orthopedics industry to do benchtop testing. Tissues engineered and developed from the whole cyclic workflow of embodiments can in turn help manufacture brain-like tissues (e.g., the prior art manufactured brain-like tissues of FIG. 13). Lab researchers can then use such manufactured tissues to conduct numerous tests without having to sacrifice living animals. Tangible products developed using embodiments—including manufactured tissues and other composites—can provide many ethical and engineering benefits to, e.g., medical device makers and biotechnologists (such as neurologists), as well as other medical professionals who work with non-linear materials like brain and heart tissues, just to name a few.

Another long-felt need addressed by embodiments relates to a lack of standardization in composite (e.g., brain tissue) samples used for experimental studies. Specifically, even when traditional soft composite samples are available for testing, the samples may not be standardized. For instance, studies may be conducted with historical composite samples using a hodgepodge of different protocols. This in turn may result in a vast range of different experimental values. Moreover, the conventional practice of performing ex vivo experiments where tissue (as an example of a composite) is first removed from a subject has the undesirable side effect of changing the tissue's properties. For example, liquid originally present in the tissue may be depleted because the tissue is drained as part of the extraction process. The original cells in the tissue may also likewise be damaged or destroyed. Yet another problem is that tissue samples may vary from subject to subject. Embodiments satisfy the long-felt need for standardization in composite samples by, among other things, leveraging AI/ML techniques with massive quantities of population data to enable systematic and consistent synthesis of engineered composite samples, e.g., the prior art manufactured tissues of FIG. 13.

### Example Closed-Loop/Feedback Process

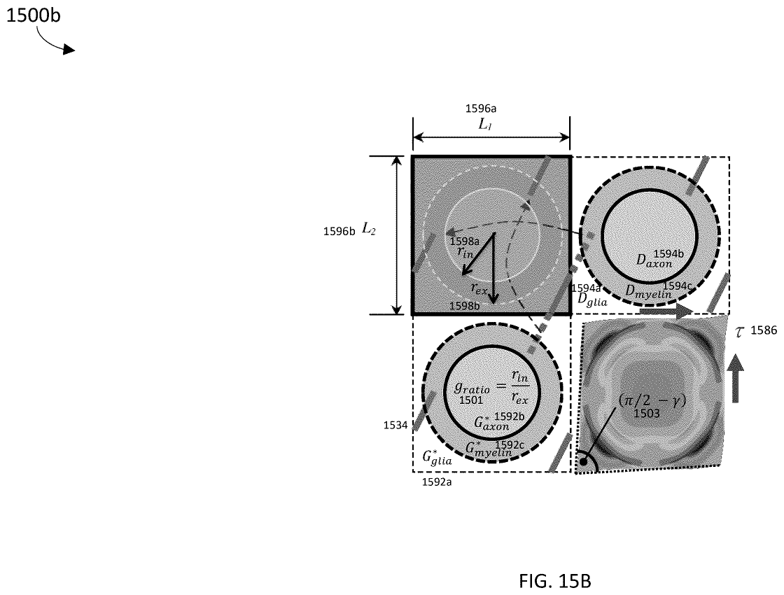

FIG. 14 is a flow diagram of a closed loop/feedback process 1400, according to an example embodiment. The process 1400 includes data input step 1410, forward modeling pass 1416, prediction step 1430, and inverse modeling pass 1418.

In an example embodiment, at an iteration of input step 1410, data concerning properties of real-world composites/materials, e.g., tissue samples such as a brain tissue, may be obtained.

According to an example embodiment, at an iteration of forward modeling pass 1416, properties obtained at an iteration of step 1410 may be used to build or construct a multi-modal forward model, e.g., multi-scale, multi-physics, and/or heterogenous hybrid model.

In an example embodiment, at an iteration of prediction step 1430, composite (e.g., tissue) properties may be predicted based on a model constructed in an iteration of forward modeling pass 1416, such as via the hybrid process 400 (FIG. 4) or hybrid method 500 (FIG. 5).

At an iteration of inverse modeling pass 1418, in an example embodiment, properties predicted in an iteration of step 1430 may then be utilized by, e.g., inverse model(s) (optionally in a suite or ensemble) such as inverse model(s) of pass 818 (FIG. 8A). For instance, according to another example embodiment, the inverse model(s) may leverage predicted properties from an iteration of step 1430 for synthesizing or engineering composites/materials/tissues. In yet another example embodiment, such engineered/synthesized materials and/or tissues may then be compared back to real-world data in a further iteration of input step 1410 as part of the closed loop/feedback process 1400 to, e.g., optimize and synthesize or manufacture best match composites/materials/tissues.

In an example embodiment, as shown in FIG. 14, forwarding modeling pass 1416 and inverse modeling pass 1418 may work hand-in-hand to iterate over time to update and train a model to reduce losses in prediction functions. For instance, according to another example embodiment, reducing losses may include minimizing loss metric(s). In yet another example embodiment, the process 1400 may include matching experimental/real-world composite/tissue/material property data to engineer or manufacture synthetic composites/tissues/bio-tissues for lab and/or industry testing applications.

According to an example embodiment, inverse modeling pass 1418 may result in or yield synthesized/engineered composites/materials. In another example embodiment, based on predicted properties of engineered materials, multi-modal inputs may then be refined or altered as follows:
a) Physics-driven modeling may be used to control parameter definitions for mechanical data input channels. For instance, physics-driven neural networks (e.g., physics-informed neural networks (PINNs)) may be employed as part of a hybrid multi-modal simulation framework for scalable composite (e.g., tissue, such as brain tissue) design and/or analysis.
b) Volumes of different phases may be modified for morphology data input channels.
c) Definitions of graph interconnects in computational models may be adjusted for electrical data input channels. For instance, these may be graph interconnects between neuronal channels, e.g., on/off linkages that depicts neuronal signal connections in a FEM.

In an example embodiment of the process 1400, after a batch of engineered/meta composite (e.g., tissue) blocks is manufactured or synthesized, the batch may be tested and results compared with actual, real-world composite data to obtain, e.g., shear, tension, and/or compression test data. According to another example embodiment, the process 1400 may be a multi-phase process that incorporates feedback from real-world physics and/or stochasticity.

### Example Framework for ML/AI Based Prediction of Single-Frequency VE BWM

Characterizing BWM using in vivo MRE and DTI is a costly, time-intensive process. Numerical modeling approaches, such as FEM models, also face limitations in fidelity, computational resources, and accurately capturing the complex bio-physical behavior of brain tissues. To address the scarcity of experimental data, researchers are exploring ML/AI as a surrogate for predicting the mechanical properties of brain tissues. Herein, an example ML/AI workflow according to an embodiment is described for predicting the homogenized VE properties of BWM using FEM-derived data. The synthetic FE dataset originates from a sensitivity analysis, whereby a triphasic 2D composite model, consisting of axons, myelin, and glial matrix, was used to simulate transverse mechanical behavior under harmonic shear stress. This dataset is utilized to train and validate ML/AI models to predict the frequency-dependent mechanical response.

In an embodiment, an example ML/AI pipeline incorporates microstructural features such as fiber volume fraction, intrinsic phase moduli, and axonal geometry to build and train regression models. Feature selection and hyperparameter optimization were applied to improve prediction accuracy. Decision tree-based models outperformed other approaches, while SHAP interpretation revealed that glial moduli and fiber volume fraction significantly influenced the predictions. This example framework according to an embodiment offers a cost-effective alternative to in vivo characterization and computationally expensive physics based direct numerical simulation methods (e.g., FEM). It also provides a basis for future ML/AI-driven inverse models to explore the impact of various brain matter constituents on neuroimaging characteristics, potentially informing studies on aging, dementia, and traumatic brain injuries.

WM, which constitutes about 50% of the brain and 60-80% of the spinal cord in humans, is highly significant in disease or senescence. Demyelination and loss of WM integrity is a core attribute in TBI, multiple sclerosis, and vascular dementia. Brain imaging techniques have revealed that demyelination leads to onset of many neurodegenerative diseases like Alzheimer's, amyotrophic lateral sclerosis, and Parkinson's disease. As brain imaging technology evolved from DTI to diffusion-weighted MRI (dMRI), they still didn't capture the axonal degeneration or inflammatory cell infiltration or mechanical injury/recovery of axons in TBI.

MRE has emerged as a solution to this by enabling extraction of local mechanical properties by interpreting propagation of harmonic shear waves (20-100 Hz). In MRE, the displacement data acquisition is used to encode the resulting shear deformation followed by the computational solution of inverse problem to extract local mechanical properties of the tissue from the displacement field. Despite tremendous progress in past 20 years, there is still room for improvement in the MRE resolution and investigate the biological basis of stiffness (i.e., MRE metrics, by extension). Thus, adopting a tissue-based model constitutes a rational step towards interpretation of MRE metrics (e.g., VE moduli) in terms of tissue microarchitecture and intrinsic properties of its constituent cells, intimately connected to both normal and pathological processes. This FEM model formed the basis of initial research done in 2019 to understand sensitivity of brain matter properties on constituent properties and RVE related parameters.

However, with increasing complexity, such computational modeling (e.g., FEMs) approaches also face their own set of challenges in terms of need for greater computation time and mesh related failure which are very common with physics-based solvers. Hence, an example data-science driven forward ML/AI solution according to an embodiment is presented, which leverages 2D VE modeled BWM FEM data from prior research to build an example forward predictive ML/AI model pipeline. Example 2D VE modeled BWM FEM data may be as described in Sullivan, D. J., et al., “Sensitivity analysis of effective transverse shear viscoelastic and diffusional properties of myelinated white matter,” Physics in Medicine Biology, 66(3), 0031-9155, 2021, p. 035027, which is herein incorporated by reference in its entirety. In an embodiment, these example ML/AI models serve to facilitate data-driven tissue characterization by eliminating the need to solve FEM codes and directly predict VE modeled brain matter properties (such as storage modulus) to interpret brain matter's VE response.

It is to be noted that the codes developed to attain the example forward ML/AI solution according to an embodiment uses aforementioned processed 2D VE FEM results as a sample dataframe/dataset to implement the ML/AI pipeline. But these proof-of-concept (POC) codes are transferrable to any other application with necessary tweaks to predict and classify non-linear composite material properties. In an embodiment, the presented example VE soft tissue data science model is a use case for the purpose of predictive ML/AI workflow development. With reasonable data-processing efforts, the same code can be used to predict properties for other composite families (both soft and hard non-linear materials via Transfer Learning).

Embodiments provide an end-to-end, data-driven ML/AI pipeline designed to predict the VE behavior—specifically, the homogenized storage moduli—of 2D BWM without relying on complex microstructural modeling or computationally intensive FE solvers. In an embodiment, this semi-modular pipeline demonstrates the ability to capture and interpret non-linear soft tissue material responses through rigorous data preprocessing and robust predictive modeling.

A framework according to an embodiment also includes an explainable SHAP modeling interpretability suite that is robust to stochastic variations, addressing uncertainties inherent in predictive ML/AI models. In an embodiment, to account for uncertainties in prediction ML/AI models, quantile regression and conformal prediction codes are embedded to quantify prediction intervals.

While a pipeline according to an embodiment was validated using a synthetic 2D VE FE dataset, its modular design ensures adaptability to broader material systems, given appropriate preprocessing. These advancements pave the way for future developments in data-driven material modeling, particularly in inverse design problems and transfer learning applications. A framework according to another embodiment also offers the flexibility to integrate regression-classification hybrid models, enabling characterization of a wide class of non-linear VE and hyperelastic composite materials.

### Example Brain Matter Tissue Characterization and Sensitivity

Advanced imaging methods such as MRE and dMRI reflect voxel-averaged (effective) properties using tissue (sub-voxel) models to account for the microstructure and intrinsic properties of the cell constituent components in each voxel. Unlike DTI, the isotropic MRE material model returns a single property pair (stiffness or storage modulus, G′, and loss modulus, G″) that is some composite of direction-dependent shear moduli, and thus is inadequate for separating contributions to tissue stiffness from axons and glia, or from their interface. BWM is known to be mechanically anisotropic under shear on the millimeter scale, especially in regions with high directional coherence, such as the corpus callosum and corona radiata. The need to choose the correct mechanical problem to invert has become more urgent as both the spatial resolution and accuracy of in vivo brain MRE continues to improve, first achieving 2 mm and then 1.6 mm isotropic voxels.

By separately exciting the brain in two different directions, the consequences of the mechanical anisotropy of BWM on MRE metrics have been shown to be very important. Isotropic inversions of the two separate displacement fields resulted in mechanical property maps that are disparate between the excitations in regions of highly aligned WM. Specifically, reconstruction of G′ and G″ in the corpus callosum, corona radiata, and superior longitudinal fasciculus revealed property differences between excitations of up to 33%.

Tissue micro-architecture's role in anisotropic models have been potently utilized to correlate the MRE metrics with normal brain aging response. Typically, MRE and DTI pulse sequences render the MRI signal sensitive to proton spin displacements on the micrometer scales. On the other hand, both clinical (in vivo) MRE and DTI have a voxel resolution limit of ˜1 mm. A known method to recover tissue microarchitecture information is to exploit the organization of WM microstructure and the underlying physics. Analogous to biophysical DTI models, candidate micromechanical models of BWM may be formulated as a unidirectional composite with myelinated axonal fibers embedded in a glial matrix. This represents a canonical topology that corresponds to realistic cyto-architectures, and which can be related to BWM micrographs extracted through brain sectioning and microscopy. Thus, a 2D FEM model of an existing approach models the physics of both MRE and DTI at the micro-scale. In this existing methodology, the DTI provides the local orientation of axons that allows for proper alignment of the micromechanical tissue in WM. Using both DTI and MRE (effective) metrics, the local intrinsic (phase-specific) properties can be extracted by the established relationship between effective and intrinsic properties through their 2D VE FEM.

As evident from the above discussion, formulating physics-based models to characterize anisotropic properties in BWM is challenging and often limited by variabilities in measurement techniques. Moreover, it has often been difficult to attain high fidelity multi-scale models to depict brain matter response. This is where example data-science driven frameworks according to an embodiment can enable characterization of BWM response using a data-driven approach to predict and classify tissue sensitivity and biomechanics response using an interpretable and efficient forward predictive ML/AI pipeline.

### Example 2D/3D FE Simulations for Brain Matter

FE simulations built on constitutive material models (such as VE, Hyperelastic) have conventionally been used to depict the brain's fibrous material structures and BWM soft fibrous tissue response to many load conditions such as large strains under quasistatic, creep/relaxation, constant strain tensile/compression, oscillatory shear, indentation, or impulsive actuation of brain tissue (or including their combinations) other than the actuation loads pertinent to brain MRE.

Utilizing published literature and established knowledge on the mechanics of composites, numerous micromechanical FE studies have been proposed that describe fibrous material structures and soft fibrous tissue response to many of the discussed load cases (including their combinations) other than the actuation pertinent to brain MRE. For an example ML/AI workflow according to an embodiment, an in-house developed triphasic BWM tissue 2D RVE model is utilized to curate a synthetic FEM dataframe. The BWM soft tissue is defined as triphasic (glia-myelin-axon) composite subjected to harmonic shear.

### ML/AI—Data Science

ML/AI techniques are used to find patterns in data or to make predictions based on experience/training on existing data. The efficacy of ML/AI programs is highly dependent on the quantity of data. In recent years, neuroscientist and brain research community has started leveraging ML/AI models to understand complex brain biomechanics, aging, and injury (e.g., TBI) response.

### Example Contributions

Contributions of embodiments include the following, for non-limiting examples:

An example end-to-end ML/AI data-science workflow for predicting effective metrics for MRE and DTI, based on a synthetic 2D FEM generated training dataset. The 2D FEM multiphasic biophysical model is based on WM cell-level microstructure contained in a tissue-based RVE.

An example ML workflow can help perform a sensitivity analysis to determine which intrinsic (microstructural and phasic) parameters are critical to RVE-averaged metrics obtained from steady state simulations. An example sensitivity analysis may be as described in Sullivan, D. J., et al., “Sensitivity analysis of effective transverse shear viscoelastic and diffusional properties of myelinated white matter,” Physics in Medicine Biology, 66(3), 0031-9155, 2021, p. 035027, which is herein incorporated by reference in its entirety. These metrics are computed in the same RVE (representing a co-registered MRE/DTI voxel) directly from the underlying physics, rather than for specific MRE or DTI sequences.

An example ML/AI predictive workflow (forward model) can establish a systematic/modular data-driven ML/AI framework capable of integrating MRE and DTI physics into not only a physics driven computational BWM models but also to leveraged AI/ML to establish a data-science driven workflow to extract these MRE/DTI metrics using state of the art ML/AI models to determine brain matter tissue sensitivity. The example framework is also developed such that it is transferrable to other material applications. Thus, an example modularized predictive ML/AI workflow would be transferrable to predicting other related soft tissue family as part of a transfer learning or model re-training approach.

### Example Materials and Methods

### Example WM VE—2D FEM

Leveraging previous computational frameworks, an MRE relevant model of BWM incorporating interactions between the axons and glial cells is used to build a 2D FEM which serves as data pool (training and test data) for an example predictive ML/AI workflow according to an embodiment. An example computational framework may be as described in Sullivan, D. J., et al., “Sensitivity analysis of effective transverse shear viscoelastic and diffusional properties of myelinated white matter,” Physics in Medicine Biology, 66(3), 0031-9155, 2021, p. 035027, which is herein incorporated by reference in its entirety. The geometry of the brain RVE has three compartments: axons, glial phase, and myelin. The glial phase consists of glial cells (such as oligodendrocytes, neurolemmocytes, and astrocytes), which maintain interactions with axons. The glial phase also has a much softer extracellular matrix (glycosaminoglycans, proteoglycans, etc.). The term “glia” is used herein to refer to the glial phase as a whole.

The axons are longitudinally aligned microtubules (nanoscale structures), which are highly cross-linked in the transverse plane. Hence in the 2D FEM dataset, the individual axons may be specified as mechanically isotropic in the plane perpendicular to their axis. The surrounding glial matrix in 2D FEM may be modeled as an isotropic continuum with uniform VE moduli. Finally, the myelin sheath around each individual axon exhibits a compact periodic nanostructure and may be considered an isotropic uniform phase.

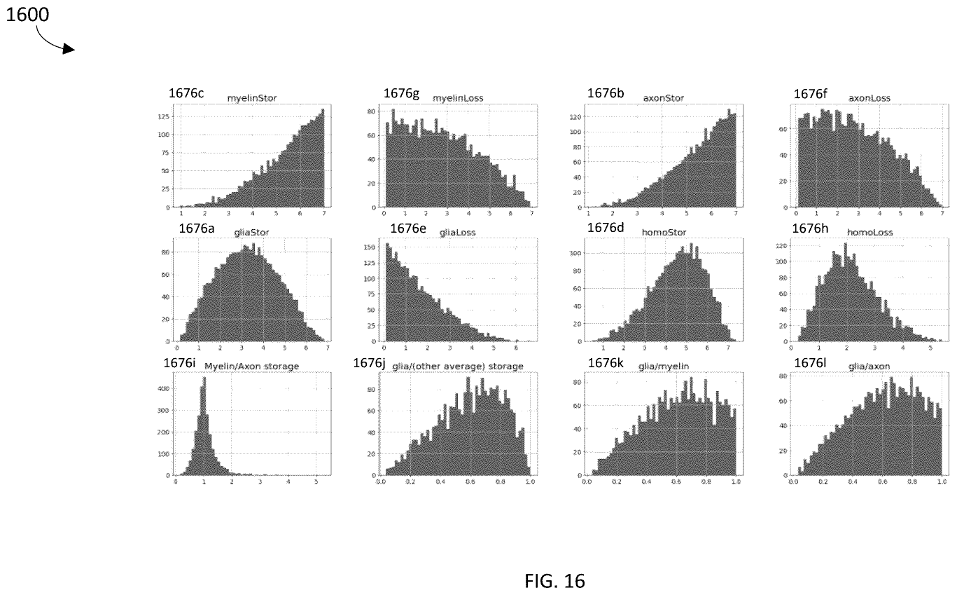

FIG. 15A is a schematic 1500a of parallel axons 1584a-1584n according to an example embodiment. The schematic 1500a illustrates axes 1, 2, and 3, planes 1-2, 2-3, and 1-3, shear stress t 1586, and displacement boundary conditions u 1588a and v 1588b on the loading planes.

FIG. 15B is a 2D RVE 1500b for a triphasic model for the myelinated axons 1584a-1584n of FIG. 15A. FIG. 15B depicts intrinsic properties G_{glia} 1592a, Gₐₓₒₙ 1592b, G_{myelin} 1592c, D_{glia} (glia diffusion coefficient) 1594a, Dₐₓₒₙ (axon diffusion coefficient) 1594b, and D_{myelin} (myelin diffusion coefficient) 1594c; asterisks (*) denote complex VE moduli, e.g., storage and loss moduli. In addition, FIG. 15B shows distances L₁ 1596a and L₂ 1596b between the planes, ratio 1501 of rᵢₙ (axon radius) 1598a to rₑₓ (overall radius of the axon plus myelin sheath thickness) 1598b, and change in angle 1503 between adjacent sides as function of shear y; diagonal lines, e.g., 1534, represent periodic matrix structures.

In an embodiment, FIGS. 15A and 15B are representative of a 2D VE FEM synthetic dataset. According to another embodiment, the dataset may include a set of solved simulations that serve as a source for an input dataset to build a forward predictive ML/AI pipeline.

In an embodiment, a resultant WM may be represented as a unidirectional composite, and each RVE may contain the cross-section of a single cylindrical axon with the surrounding myelin annulus, immersed in glial matrix, in contrast with FIG. 15B. According to another embodiment, all three RVE constituents, i.e., axon, myelin, and glia, may be perfectly bonded.

### Example Computational Mechanical Model Component

### Example Mechanical Model—Physics Based 2D VE FEM

In an embodiment, an example BWM 2D FEM mechanical model is formulated by applying a force balance in the triphasic RVE which is treated as continuum media. In example Eq. 1 below, ρ is the density, which may be the same for all three constituents. ∇·σ signify the divergence formula for the Cauchy Stress (σ), u is the displacement vector in the brain RVEs (function of space and time).

$$∇ \cdot σ = ρ \frac{{\partial }^{2} u}{\partial {t}^{2}} \qquad ( 1 )$$

According to an embodiment, in the developed micro-mechanical FEM, a linear isotropic constitutive relationship is considered in each phase between the stress and strain ε as described in example Eq. 2 below:

$$σ = [ \frac{{E}_{P}}{3 ( 1 - 2 {v}_{P} )} - \frac{2 {G}_{P}}{3} ] t r ( ε ) I + 2 {G}_{P} ε ; \qquad ( 2 )$$

$$ε = \frac{1}{2} [ ∇ u + {( ∇ u )}^{T} ] .$$

In resultant mechanical model's stress equation, E_{P} denotes the Young modulus, G_{P} is the shear modulus, and ν_{P} is the Poisson ratio to describe the piece-wise mechanical properties of each constituent phase as indicated by the subscript p. tr(ε) is the trace of the strain tensor and I is the second-rank identity tensor.

### Example Boundary Conditions

Referring to FIGS. 15A and 15B, in an embodiment, the WM RVE system is excited by imposing harmonic shear stress at its two opposite boundaries, in a spatially periodic manner, and at a single frequency (e.g., 50 Hz) that is typically used for in vivo brain MRE imaging. The tri-phasic BWM tissue model is subjected to these MRE loading conditions. The time-dependent response of biological soft tissue materials to impulse or step function loads suggested suitability of linear viscoelasticity theory.

Average pure shear strain, γ, is applied on the plane 2-3 of the RVE. The estimated shear stress t 1586 is shown in FIG. 15A. Example detailed analytical modeling equations may be as described in Sullivan, D. J., et al., “Sensitivity analysis of effective transverse shear viscoelastic and diffusional properties of myelinated white matter,” Physics in Medicine Biology, 66(3), 0031-9155, 2021, p. 035027, which is herein incorporated by reference in its entirety.

### Target Property for Example Forward ML/AI Workflow

In an embodiment, for the purpose of an example data-science ML/AI workflow, the output variables of concern from the developed mechanical FEM model are frequency dependent components

$${G}_{eff}^{′} and {G}_{eff}^{′′}$$

of homogenized storage and loss moduli. The output parameter (target variable) for the example forward model is the homogenized storage modulus. These parameters are homogenized over all three constituent phases in the 2D BWM FEM RVE. They can be evaluated using Fourier Transforms (FT) in terms of \tilde{g}(ω), which is the complex FT of the shear relaxation function

$$g ( t ) = \frac{{G}_{R} ( t )}{{G}_{∞}} - 1.$$

The resultant equations are example Eq. 3 and Eq. 4 below:

$${G}_{eff}^{′} ( ω ) = {G}_{∞} ( 1 - ω𝔍 ( \tilde{g} ) ) \qquad ( 3 )$$

$${G}_{eff}^{′′} ( ω ) = {G}_{∞} ( ωℜ ( \tilde{g} ) ) \qquad ( 4 )$$

G_{R}(t) and G_{∞} represent the time-dependent shear relaxation modulus and the steady state shear modulus. [symbol] (\tilde{g}),ℑ(\tilde{g}) denote the real and imaginary parts of \tilde{g}(ω), respectively. This overview of the mechanical FEM target quantities may facilitate physical modeling in context of soft tissue characterization. Described herein are example forward data-science ML/AI models according to embodiments to help bring down computational time at continuum scales by facilitating data-driven approach to predict properties such as homogenized moduli for myriad scenarios ranging from steady state dynamics (SSD), general static to explicit dynamic models.

### Example FEM Solution Steps

In an example embodiment, a FEM steady-state dynamic solver, in, e.g., Abaqus, is used to derive the response of the RVE under a steady harmonic load of 50 Hz. The load is applied as a displacement B.C. on the surface nodes, with a harmonic displacement parallel to the face, resulting in a pure shear distortion of the RVE, with a shear strain of γ=0.01. The RVE faces in the shear plane are assigned a repeated boundary condition, where each node's displacement is matched to a corresponding node on the opposing face.

After the steady state harmonic field is computed, the reaction forces necessary to produce the assigned displacements are measured and summed for each face. The resultant average complex shear stress is consequently determined. The effective shear modulus of the brain matter RVE is computed based on the pure shear stress loading value and correlated average complex shear strains. This forms the basis for the synthetic FEM output data frame curation which is used as a sample dataset to build the example forward ML/AI pipeline according to an embodiment.

### Example VE Material Model Definition—BWM

In the sample dataset according to an embodiment, the constituent phases are assigned isotropic mechanical and diffusional properties, which are piece-wise uniform. The stiffness and viscosity of the components increase as glial matrix<composite<myelinated axon. According to an embodiment, example material properties were interpolated using a power-law relationship as function of frequency, for obtaining the glial properties at 50 Hz, as shown in Table 1 below:

TABLE 1
Example mechanical material properties of 2D VE BWM RVEs.

| Material | | | |
|---|---|---|---|
| component | Storage Moduli (Pa) | Loss Moduli (Pa) | Element Type |
| Axon | ${G}_{axon}^{′} = 2200$ | ${G}_{axon}^{″} = 1804$ | Quad |
| Glia | ${G}_{glia}^{′} = 500$ | ${G}_{glia}^{″} = 4 \; 10$ | |
| Myelin | ${G}_{myelin}^{′} = 3500$ | ${G}_{my elin}^{′} = 2870$ | |

In computational or numerical modeling of non-linear soft composites, homogenization techniques are often deployed to extract effective mechanical properties by averaging the stress-strain relationship over 2D or 3D RVEs. An exact description of the VE and diffusion responses of the tissue is not feasible as function of its micro-architecture and intrinsic material properties of constituent phases (axon, glia, and myelin). Previous approaches attempt to functional map and explain these relationships, which constitutes the physics based 2D FEM used in an example ML/AI workflow according to an embodiment.

$$[ {G}_{eff}^{′} , {G}_{eff}^{′′} , {D}_{eff} ] = {ℱ}_{1} ( {VF}_{myelin} , {VF}_{axon} , {G}_{p}^{′} , {G}_{eff}^{′′} , {D}_{p} ) \qquad ( 5 )$$

According to an embodiment, in example Eq. 5 above, [symbol] ₁ maps intrinsic properties (subscripted with p) to derive effective shear storage modulus and shear loss modulus of the tissue RVE, and the effective diffusion coefficient as a function of geometrical parameters (VF of constituent phases). In another embodiment, for setting up the FE model in an example ML/AI workflow, the FEM model was initialized with following intrinsic properties:

$${G}_{axon}^{′} , {G}_{glia}^{′} , {G}_{myelin}^{′} , {G}_{axon}^{′′} , {G}_{glia}^{′′} , {G}_{myelin}^{′′} , {D}_{axon} , {D}_{glia} , {D}_{myelin} ,$$

and gᵣₐₜᵢₒ, the latter of which is a dimensionless parameter to describe the myelin thickness. According to an embodiment, gᵣₐₜᵢₒ may be defined as a ratio between axon diameter and total fiber diameter, as in 1594 of FIG. 15B. In another embodiment, gᵣₐₜᵢₒ may relate to the geometric parameters as follows:

$$\frac{{VF}_{myelin}}{{VF}_{axon}} = \frac{1 - {g}_{ratio}^{2}}{{g}_{ratio}^{2}} \qquad ( 6 )$$

In an embodiment, for the steady-state dynamic FEM simulation, the effective shear storage and shear loss moduli are dependent on the angular frequency (ω), of the harmonic loading since the intrinsic properties are also frequency-dependent. According to another embodiment, by defining a fiber volume fraction, VF=VFₐₓₒₙ+VF_{myelin}, the above example Eq. 5 and Eq. 6 can be combined as follows:

$$[ {G}_{eff}^{′} ( ω ) , {G}_{eff}^{′′} ( ω ) , {D}_{eff} ] = {ℱ}_{2} ( VF , {g}_{ratio} , {G}_{p}^{′} , {G}_{p}^{′′} , {D}_{p} ) \qquad ( 7 )$$

In prior sensitivity analysis research, it was demonstrated that mapping [symbol] ₂ is computed by developing a mechanical model separately from the diffusion model for the same brain RVE, and then sensitivity analysis was conducted using set of inputs on the righthand side of example Eq. 7 above. An example sensitivity analysis may be as described in Sullivan, D. J., et al., “Sensitivity analysis of effective transverse shear viscoelastic and diffusional properties of myelinated white matter,” Physics in Medicine Biology, 66(3), 0031-9155, 2021, p. 035027, which is herein incorporated by reference in its entirety.

### Example Data-Science Driven Forward Solution Methodology

An example embodiment may leverage prior sensitivity analysis, which systematically analyzed impact of various intrinsic properties on effective BWM RVE properties. An example sensitivity analysis may be as described in Sullivan, D. J., et al., “Sensitivity analysis of effective transverse shear viscoelastic and diffusional properties of myelinated white matter,” Physics in Medicine Biology, 66(3), 0031-9155, 2021, p. 035027, which is herein incorporated by reference in its entirety. An example data-science driven workflow according to an embodiment, e.g., a forward ML/AI model pipeline, is provided that can be deployed to predict soft-tissue properties using a data-driven (ML/AI driven modeling) approach instead of running conventional time-consuming physics based FEM solvers to derive homogenized/effective tissue moduli.

In an embodiment, the curated synthetic dataset from FEM solver has total 16 columns (features) and 2,500 set of simulations were carried out in Abaqus to generate the dataset for building an example forward ML/AI workflow. The FEM generated dataset has a few intrinsic material parameters defining the FEM setup, namely:

$${g}_{rato} , VF , {G}_{axon}^{′} , {G}_{axon}^{′′} / {G}_{axon}^{′} , {G}_{myelin}^{′} , {G}_{myelin}^{′′} / {G}_{myelin}^{′} , {G}_{glia}^{′} , and {G}_{glia}^{′′} / {G}_{glia}^{′} .$$

In all the FEM simulations for the mechanical property computations, the Poisson ratio is set close to 0.5 (υₚ=0.4995) to account for the near incompressibility of BWM. In the brain RVE, the axon diameter is kept fixed and equal to 0.7 μm, but the fiber VF is varied by tuning the overall RVE size.

### Example Data Science Driven Forward ML/AI—Workflow

### Example Dataset Characteristics—2D FEM Solved Data (Synthetic Dataset)

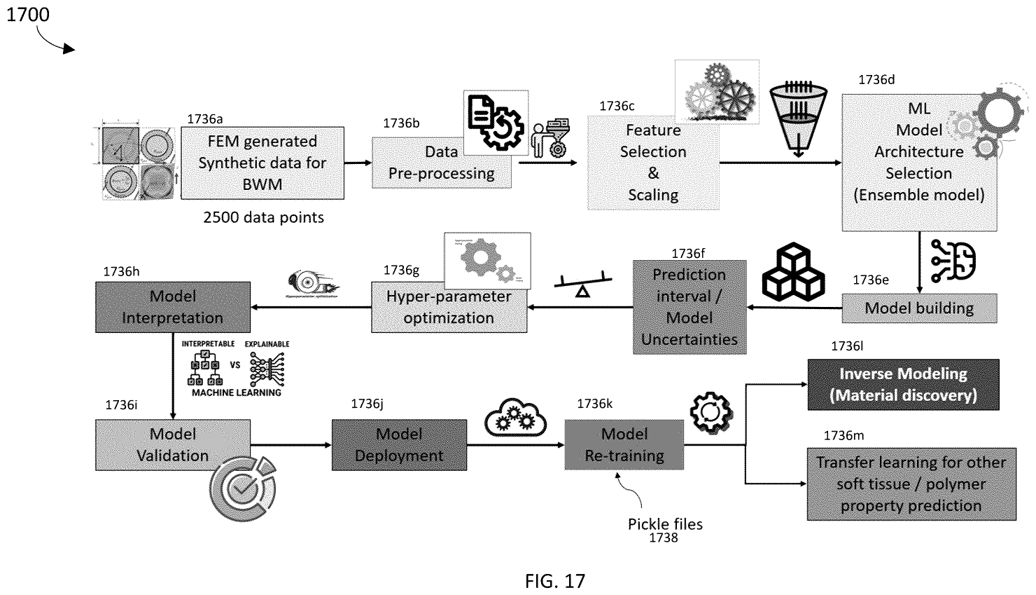

FIG. 16 is a plot 1600 of distributions for key variables 1676a-16761 in a 2D FEM VE modeled BWM dataset according to an example embodiment. In an embodiment, FIG. 16 shows trends of model parameters (input variables) and homogenized storage modulus (output/target variable) of an example workflow.

According to an embodiment, exploratory data analysis (EDA) is first conducted to check the distribution in data frame obtained from the solved 2D FEM results database. The curated 2D FEM dataset contains variables with different types of distributions, including normal, skewed (both left and right), and uniform distributions. The presence of skewed distributions (both left and right) may indicate that some variables may have outliers or extreme values that are either very low or very high. As shown in FIG. 16, the normal distribution of some variables, e.g., gliaStor 1676a and homoStor 1676d, implies a symmetric spread of data, which may indicate that these variables are well-behaved in statistical analyses. The diverse distribution shapes indicate that different statistical or ML/AI models may be needed to handle these variables effectively, depending on the goal of the analysis.

Right-skewed distribution (positively skewed) means that the tail on the right side (higher values) is longer, indicating that most data points are concentrated at lower values, with fewer higher values. Left-skewed distribution (negatively skewed) means that the tail on the left side (lower values) is longer, indicating that most data points are concentrated at higher values, with fewer lower values.

The histogram distribution plot 1600 on the curated dataset provides insights into the distribution of various variables. Some of the key information observed as follows: myelinStor 1676c and axonStor 1676b are left-skewed distributions, i.e., most data points are higher. myelinLoss 1676g and axonLoss 1676f is right-skewed distributions, where most data points are lower. Values for both gliaStor 1676a and homoStor 1676d (an example target property value for an ML/AI workflow) variables are normally distributed, centered around a specific value, indicating a balanced spread of data around the mean. On the other hand, gliaLoss 1676e and homoLoss 1676h variables are left-skewed, similar to myelinLoss 1676g and axonLoss 1676f.

As shown in FIG. 16, Myelin/Axon storage 1676i values shows a distribution with a significant peak at a low value, suggesting that many data points are concentrated around a lower range. Glia/(other average) storage 1676j value distribution is relatively uniform with a slight peak, indicating a moderate spread of data points across the range with a small concentration at certain values. Glia/Myelin 1676k and Glia/Axon 16761 display somewhat uniform distributions with multiple peaks, suggesting that the data may have sub-groups or modes within the overall population.

### Example ML/AI Forward Modeling Workflow

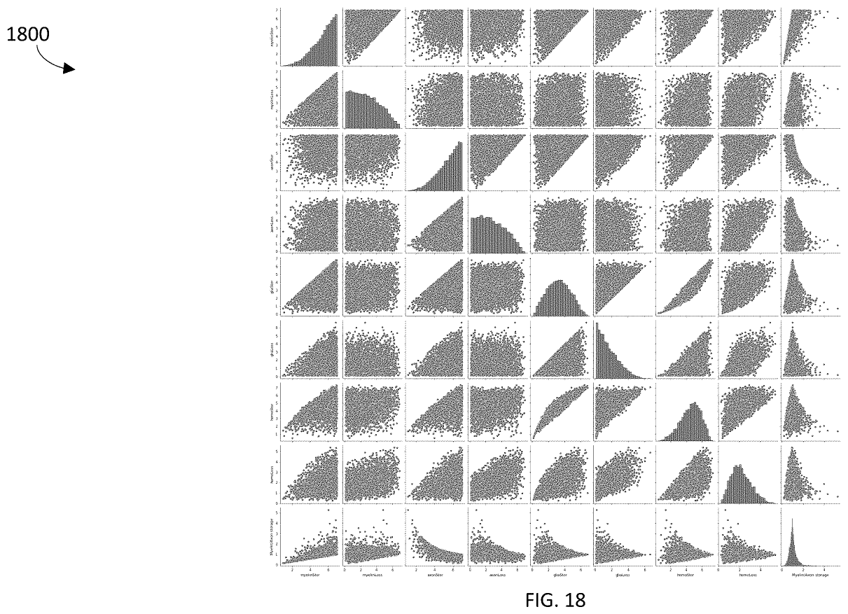

FIG. 17 is a block diagram of a forward ML/AI predictive modeling workflow 1700 depicting all stages 1736a-1736m of the model implementation process 1700 according to an example embodiment. In an embodiment, the workflow 1700 can be extended to other material domains (e.g., besides the used dataset of soft tissue composites) to characterize material response. According to another embodiment, models 1700 can also be leveraged to depict other families of soft tissue using transfer learning 1736m and aid synthetic tissue generation/material modeling using inverse modeling schema 17361 to aid material discovery.

In an embodiment, the workflow 1700 presented in FIG. 17 outlines an example ML/AI based forward modeling approach for the mechanical response (homogenized storage modulus) prediction of VE modeled BWM. The framework 1700 initiates with the generation 1736a of synthetic data from 2D FE models described hereinabove with respect to example WM VE 2D FEM. The obtained solved FE output results are then post processed using, e.g., SQLite® and/or R packages to record all completed simulation data. In total about 2,500 data points are synthetically generated to serve as training and test dataset for implementing the forward ML/AI pipeline 1700.

Next, the derived data is imported into, e.g., Python, and converted to, e.g., a pandas dataframe. Once the dataset is imported, it is then followed by data pre-processing 1736b, feature selection and/or scaling 1736c to refine the dataset. Subsequently, the pipeline 1700 proceeds with ML/AI model architecture selection 1736d—emphasizing, e.g., ensemble models—and comprehensive model building 1736e to capture the complex material behavior. Hyper-parameter optimization 1736g and assessment of prediction intervals are implemented to enhance model performance and evaluate prediction uncertainties 1736f.

The iterative nature of the workflow 1700 ensures robust model interpretation 1736h, validation 1736i, and deployment 1736j, with a focus on creating explainable machine learning solutions. Once validated, the model may be used for inverse modeling 17361, aiding in the discovery of material properties and/or enabling transfer learning 1736m for other soft tissues or polymer property predictions. The inclusion of re-training 1736k and refinement steps using stored model parameters 1738 (e.g., Pickle files) ensures adaptability and continual improvement of the framework 1700.

### Example Data Pre-Processing

In an embodiment, at step 1736 of the workflow 1700, the EDA is conducted to check the data distribution from the solved 2D FEM database. Next, all the standard data pre-processing checks are performed on the input dataframe (e.g., an FE model output database that was saved as a pandas dataframe). This includes checking for null values, cases with missing values, for non-limiting examples. Also, check for the data type in the dataframe (df) and convert categorical data columns into one-hot encoded (OHE) numerical values, for non-limiting examples.

### Example Correlation Analysis

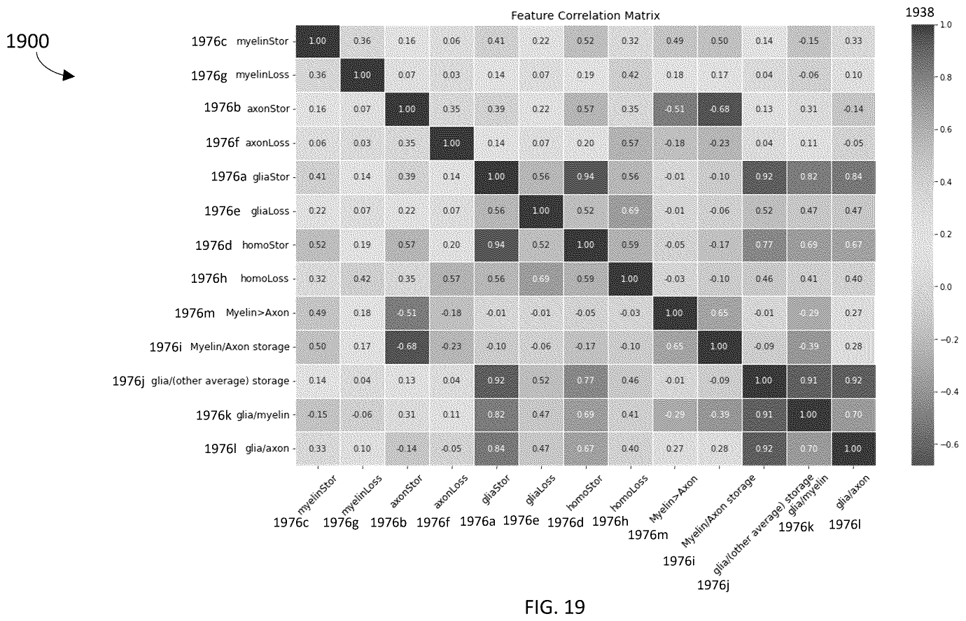

FIG. 18 is a pair plot 1800 visualizing relationships between multiple features in the 2D FEM dataset of FIG. 16. In FIG. 18, the diagonal elements display the individual feature distributions, while the off-diagonal scatter plots depict pairwise relationships. Strong linear correlations appear as diagonal trends, whereas non-linear dependencies and independent features exhibit scattered distributions. This visualization 1800 helps identify potential feature correlations, redundancies, and non-linear patterns for preprocessing step 1736b (FIG. 17) in the example predictive ML/AI workflow 1700 (FIG. 17).

In an embodiment, correlation analysis helps determine understanding linear and non-linear relationships between the input variables of a dataset. The scatterplot approach also highlights no clear relationship cases for respective variables. In FIG. 18, diagonal plots show histogram for each feature (normal, skewed or uniform distribution trend). Bi-modality and multi-modality distribution indicate presence of multiple clusters or categories in the data. Highly correlated features may be dropped to eliminate redundancy and also reduce computation time.

### Example Feature Engineering and Selection

In an embodiment, as part of the feature engineering and feature selection process 1736c (FIG. 17), one or more of the below methods may be implemented, for non-limiting examples:

### Removing Quasi-Constant Features

In an embodiment, this method is designed to remove “quasi-constant” features from the input dataframe. The main purpose of the code is to identify and exclude features that have very little variance, meaning their values are almost the same for all the samples. Such features contribute very little to model performance and can potentially lead to overfitting or increased computational costs.

According to another embodiment, the defined method uses the VarianceThreshold class from sklearn to identify and remove quasi-constant features—features with low variance (less than 0.01). It initializes VarianceThreshold with threshold=0.01, fits it on the dataframe to find features meeting the threshold, and then identifies which features are retained. The code then prints the names of features that were excluded and returns the filtered dataframe containing only the retained features.

### Removing Constant Features

In an embodiment, the constant_feats function identifies constant features (columns with zero standard deviation) using a list comprehension. It then removes those constant features and only the non-constant features are retained. This check helps filter out constant value features as they do not provide useful information for analysis or modeling.

### Removing Duplicates

According to an embodiment, the “remove duplicate features” function removes duplicate features (columns), by identifying duplicated rows in the transposed dataframe using duplicated( ) and storing the indices of these duplicated features. It then drops these duplicates using drop_duplicates(keep=‘first’) and transposes the dataframe back to its original format, ensuring only unique features are retained. The modified dataFrame (2D FEM generated dataset for ML/AI workflow 1700) with unique columns is returned. This process helps eliminate redundant features that are identical across all rows.

### Removing Correlated Features

In an embodiment, the correlation function identifies and removes highly correlated features based on a specified threshold. Using the calculated correlation matrix and iterating through the matrix to find pairs of features with absolute correlation values greater than the specified threshold. When a pair is found, it adds the column name of the latter feature (to avoid duplication) to the set col_corr. At last, the set of column names that are considered highly correlated is retrieved and removed to reduce redundancies.

### Analysis of Variance (ANOVA)

According to an embodiment, the feature selection 1736c (FIG. 17) for a regression problem may use ANOVA F-test statistics. Using the SelectKBest class with the f_regression scoring function, it selects the top five features that have the highest correlation with the target variable y. The selected features are identified using get_support( ) and are printed along with the shape of the transformed dataset, which now only contains the most relevant features. This helps in reducing the dimensionality of the dataset by keeping only the features that contribute the most to the regression model.

### Least Absolute Shrinkage and Selection Operator (LASSO) Regularization

LASSO is a type of linear regression that performs feature selection by adding an L1 penalty to the loss function. The penalty forces the regression coefficients of less important features to become zero, effectively removing them from the model. This approach is useful when there are many features and it is desired to retain only the most significant ones.

In the model pipeline 1700, according to an embodiment, LASSO function standardizes the feature values using scaling functions (standard/min-max) to ensure all features are on the same scale. LASSO then initializes a SelectFromModel object with a chosen ML/AI model 1736d (FIG. 17) from model builder code 1736e (FIG. 17)) using the L1 penalty (penalty=‘L1’), which induces sparsity by shrinking less important feature coefficients to zero. The model is trained on the scaled training data and get_support( ) method is used to identify the features selected by LASSO.

### Pearson's Correlation

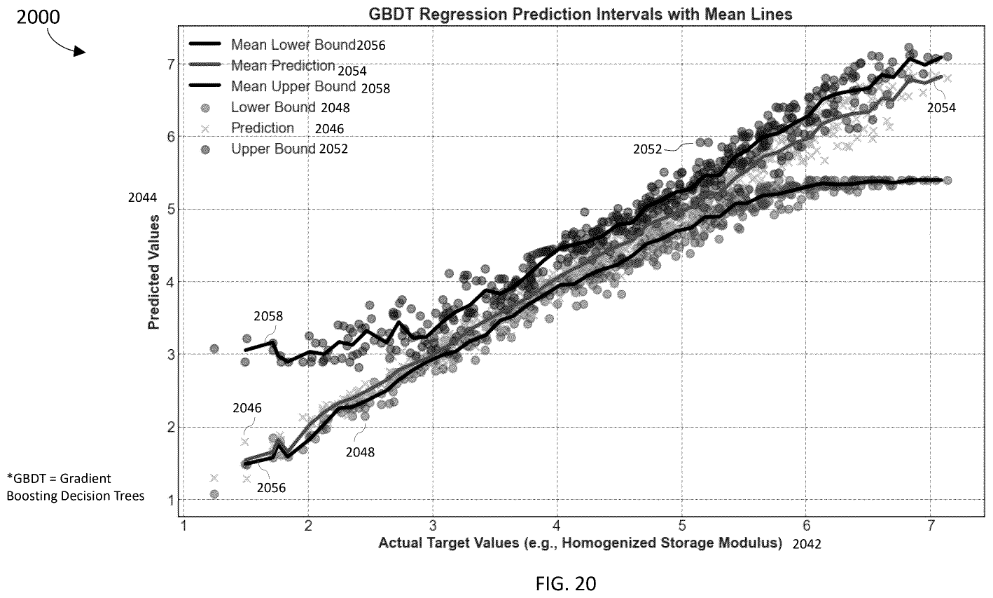

FIG. 19 is a heatmap representation of a correlation matrix 1900 for the synthetic 2D FEM dataset of FIG. 16. As shown in FIG. 19, the shading scale 1938 indicates the strength of relationships between features 1976a-1976m, where darker shading represents strong positive and negative correlations, and lighter shading indicates weak or no correlation. In an embodiment, this visualization 1900 helps identify feature dependencies, multicollinearity, and potential feature selection 1736c (FIG. 17) opportunities for the ML/AI models.

Pearson's Correlation measures the linear relationship between two variables 1976a-1976m, ranging from −1 to 1, as illustrated in FIG. 19. According to an embodiment, in feature selection 1736c, Pearson's correlation coefficient is used to assess the strength and direction of the relationship between each feature and the target variable. Features with low absolute correlation values are often removed, as they are less likely to contribute significantly to predicting the target.

In an embodiment, the pearson_colinear_detector function identifies pairs of collinear features in the given 2D FEM dataframe using Pearson's correlation coefficient. It first initializes an empty dictionary colinear_dict to store results. Then, for each feature (column) in the DataFrame, it calculates the absolute correlation matrix and sorts the correlation values in descending order for that column. It filters out features that have a correlation coefficient greater than 0.8 (indicating high collinearity) and excludes the column itself (since a column is always perfectly correlated with itself, with a value of 1). These highly correlated features are stored in a list, and the function adds this list to colinear_dict under the corresponding column name. Finally, the function returns colinear_dict, which contains all columns and their corresponding lists of highly collinear columns, making it easier to identify and handle multicollinearity in the dataset.

### Univariate Feature Selection Check

Univariate feature selection assesses each feature independently using statistical tests (e.g., ANOVA F-test, chi-squared test) to determine the strength of its relationship with the target variable. Only features that pass a specified significance threshold are retained. This technique is useful for quickly identifying individual features that are most predictive of the target variable.

According to an embodiment, the univariate_FS function is coded to perform univariate feature selection on the given training dataset and target variable using the F-test for regression (f_regression). It starts by calculating the F-scores (f_val) and corresponding p-values (p_val) for each feature in X_train using f_regression. These values indicate the relevance of each feature in predicting y. The function then creates a dictionary, feature_dict, where the feature names are stored as ‘features’ and their respective F-scores as ‘f_score’. This dictionary is converted into a pandas DataFrame and sorted in descending order based on the F-scores. The sorted dataframe is useful for identifying the most predictive features. The function returns the top features based on the F-scores for further model development.

### Backward Selection

Backward selection (also known as stepwise regression) is an iterative feature elimination method that starts with all features in the model and removes the least significant one at each step based on a specific criterion (e.g., p-value, Akaike information criterion (AIC)). The process continues until only the most relevant features remain. This approach is effective in refining models by eliminating redundant or irrelevant features.

In an embodiment, the back_selection function implements backward feature selection to iteratively remove the least significant features from the input (2D FEM dataframe) based on their p-values until all remaining features have a p-value below a specified threshold (threshold_out, default=0.05). The process starts by including all columns from input dataframe in the list included. It then fits an Ordinary Least Squares (OLS) regression model using the statsmodels library (sm.OLS) with the target variable (homogenized storage modulus) and the features currently in included. The model's p-values for each feature (excluding the constant) are calculated, and the feature with the highest p-value (worst_pval) is identified. If worst_pval is greater than the threshold_out value, it indicates that the feature is not statistically significant, and this feature is removed from included. This process is repeated until no remaining features have a p-value higher than the specified threshold. The function then returns the final list of included features that are statistically significant in predicting target.

According to an embodiment, for an example dataset, LASSO may be selected as the best feature selection method. The top three features from the LASSO feature selection method and their contribution to model prediction are discussed hereinbelow with respect to example model interpretability and explainability.

### Example Feature Scaling

In an embodiment, as part of the feature scaling process 1736c (FIG. 17), one or more of the below methods may be implemented, for non-limiting examples:

### Normalization

Feature normalization is also known as min-max scaling or min-max normalization. It is the simplest method and consists of rescaling a range of features to scale a range [0,1].

### Standardization

Feature standardization makes the values of each feature in the data have zero mean and unit variance. The general method of calculation is to determine the distribution mean and standard deviation for each feature.

### Example Model Architecture—Model Builder

According to an embodiment, multiple regression models were implemented and compared to evaluate their predictive performance. The models included Linear Regression, Multilayer Perceptron (MLP) Regressor, Random Forest Regressor, and GBDT, for non-limiting examples.

Linear Regression was used as a baseline model, where the relationship between features and the target variable was established using ordinary least squares. Feature importance was analyzed through coefficients, and model performance was evaluated using metrics such as Mean Squared Error (MSE) and R-squared score.

MLP Regressor was applied to capture non-linear relationships using a neural network-based approach. With the rectified linear unit (ReLU) activation function and the Adam solver, the network was trained to minimize the loss over 500 iterations. The resulting model was assessed for accuracy on the test set, along with its root MSE (RMSE).

Random Forest Regressor was used to capture complex interactions between features by building an ensemble of decision trees. The model was fit using 100 trees and a maximum depth of two to prevent overfitting. Feature importance was also quantified based on the impurity reduction criterion, and the model's accuracy was evaluated using mean absolute percentage error (MAPE).

GBDT were employed to improve predictive performance by sequentially fitting decision trees to the residuals of prior models. Hyperparameters such as learning rate, number of estimators, and maximum tree depth were optimized. Performance metrics, including MSE and RMSE, were calculated to compare the effectiveness of boosting against other models.

In an embodiment, these models were trained and tested on a consistent dataset, and their performance was evaluated using key metrics, allowing for a robust comparison of their predictive capabilities. Some other model builder functions coded: ridge regression, elastic net regression model and lasso regression model.

### Example Predictive Model—Uncertainty Analysis

Prediction intervals are essential for quantifying uncertainty in ML/AI models, providing a range within which a future observation is likely to fall with a specified probability. This analysis step 1736f (FIG. 17) in the example ML/AI workflow 1700 (FIG. 17) estimates the range for future observations of the homogenized storage modulus, considering both data variability and model uncertainties. While confidence intervals estimate the uncertainty of a population parameter, prediction intervals focus on individual data points, which is particularly relevant for ML/AI models making predictions for specific observations rather than for a broader population.

Several example approaches exist for constructing prediction intervals, each with unique considerations and complexities depending on model type, data distribution, and the specific application. Common methods include parametric techniques, bootstrap (resampling), quantile regression, Bayesian approaches, and ensemble-based methods such as quantile regression forests and conformal predictions, for non-limiting examples.

### Example Prediction Interval Methods in VE Sensitivity Analysis ML/AI Workflow

In the example ML/AI framework 1700 (FIG. 17), two example prediction interval methods have been explored. Quantile and Conformal prediction interval codes were developed to estimate uncertainties in predicted homogenized storage modulus values for GBDT, LGBM, and random forest ML/AI models.

### Example Quantile Regression Prediction Intervals

### GBDT Prediction Intervals

The GBDT model was trained to generate central predictions and estimate prediction intervals using the 5^{th} and 95^{th} percentiles, offering insights into model uncertainty. Separate GBDT regressors were trained for the median (α=0.5) and lower and upper quantiles (α=0.05 and α=0.95). The model parameters included 100 estimators, a learning rate of 0.1, a minimum sample split of two, and a maximum depth of three. Performance was evaluated using the R² score, with visualizations including scatter plots and smoothed trend lines for each interval.

This approach leverages the ‘quantile’ loss function to generate asymmetric prediction intervals, making it effective for capturing heteroscedasticity and varying levels of uncertainty across the target variable. The method's flexibility is evident in its ability to adapt to local variations, reflecting the inherent complexities in the data.

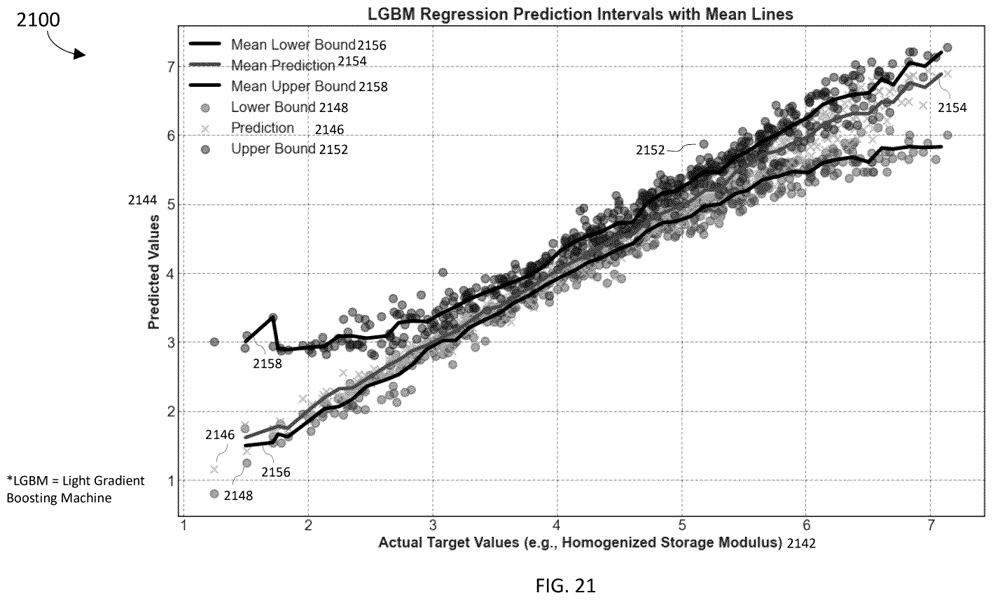

FIG. 20 is a plot 2000 of predicted values 2044 versus target values 2042 illustrating prediction intervals 2046, 2048, 2052 and uncertainty quantification for a GBDT regressor model according to an example embodiment.

In an embodiment, the plot 2000 shows the prediction intervals 2046, 2048, 2052 and mean trends 2054, 2056, and 2058 for a GBDT regressor applied to the test dataset. The R² score of 0.9839 indicates that the model has a high degree of fit, capturing over 98% of the variance in the target values. The visualization 2000 includes the central predictions 2046 along with the lower 2048 and upper 2052 bounds, representing the 5^{th} and 95^{th} percentiles, respectively.

### LightGBM Prediction Intervals

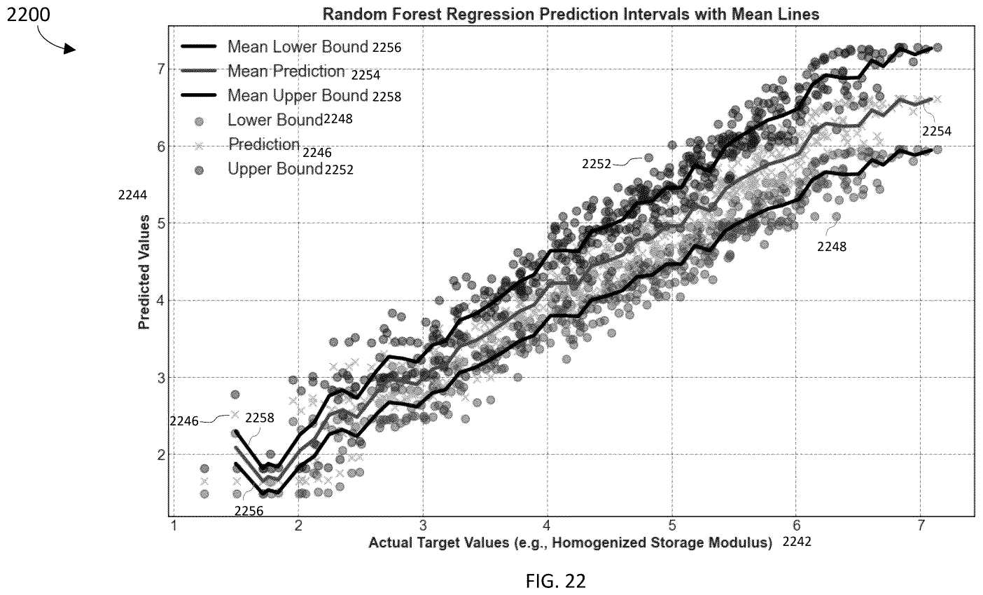

FIG. 21 is a plot 2100 of predicted values 2144 versus target values 2142 illustrating prediction intervals 2146, 2148, 2152 and mean trends 2146, 2148, 2152 for a LGBM regressor model according to an example embodiment. The plot 2100 shows the lower 2148 and upper 2152 prediction bounds along with central predictions 2146 for the test dataset.

The LightGBM model exhibited a performance similar to GBDT, with an R² score of 0.9835 compared to GBDT's 0.9839, indicating that both models explain over 98% of the variance. However, the LightGBM model showed slightly more variability in prediction intervals at lower target 2142 values (2-3 range), suggesting increased sensitivity to data fluctuations. The narrow intervals in the mid-range (3-5) and wider intervals at the extremes (<2 and >6) suggest that LightGBM may have higher uncertainty at the distribution tails, as illustrated by FIG. 21.

Like the previous GBDT model, this plot 2100 also shows the mean lines 2146, 2148, 2152 for each interval 2146, 2148, 2152 to illustrate the general trend of the predictions 2144 across actual target values 2142. With the R² score of 0.9835 for the LGBM model, the performance is nearly identical to the GBDT model, which had an R² score of 0.9839. This indicates that both models explain approximately 98.3% of the variance in the target values 2042 and 2142, respectively, reflecting strong predictive capabilities.

### Random Forest Prediction Intervals

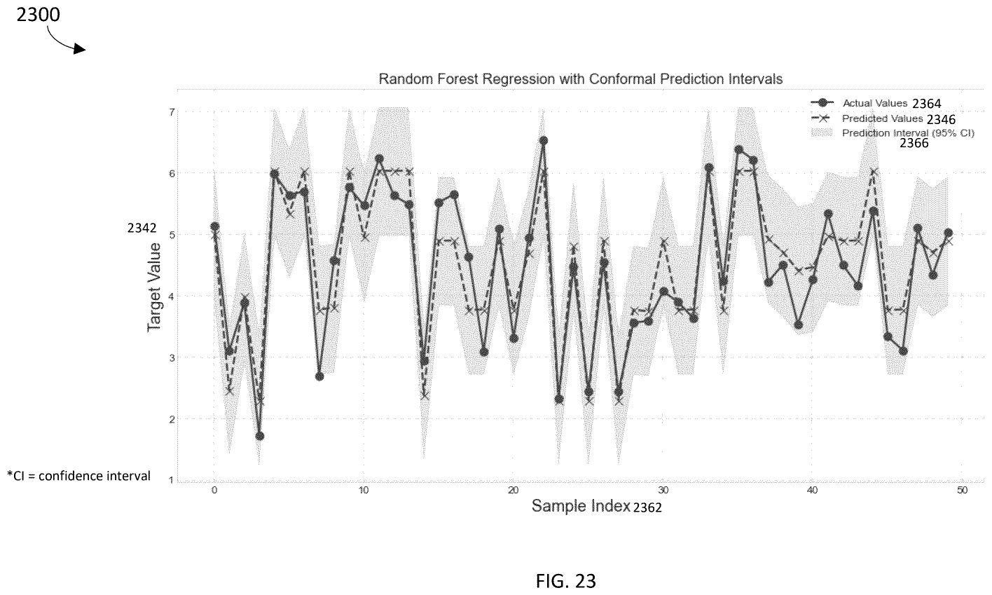

FIG. 22 is a plot 2200 of predicted values 2244 versus target values 2242 illustrating prediction intervals 2246, 2248, 2252 and mean trends 2254, 2256, 2258 for a random forest regressor model according to an example embodiment.

The Random Forest (RF) model, in comparison, achieved a lower R² score of 0.9562, indicating reduced predictive accuracy. The wider prediction intervals 2246, 2248, 2252, particularly at the extremes, suggest a higher degree of uncertainty, as illustrated in FIG. 22. The variability in trend lines 2254, 2256, 2258 indicates that the RF model may struggle with capturing stable trends, especially at lower and upper values 2242, making it less reliable than the GBDT and LightGBM models.

GBDT has the tightest intervals 2046, 2048, 2052 and best fit, while LGBM performs similarly but with slight deviations at low values 2142. Overall, GBDT is the most stable and accurate, followed by LGBM, with RF being the least reliable.

The RF model has a lower R² score (0.9562) compared to GBDT (0.9839) and LGBM (0.9835), indicating reduced predictive accuracy. The RF intervals 2246, 2248, 2252 are wider, especially at lower and upper extremes, showing higher uncertainty. RF's mean trend lines 2254, 2256, 2258 are less smooth, reflecting instability in predictions 2244, as illustrated in FIG. 22.

### Example Conformal Prediction Intervals

In an embodiment, to further analyze uncertainty, conformal prediction intervals were implemented using the Model Agnostic Prediction Interval Estimation (MAPIE) library with a Random Forest base model. The conformal approach constructs prediction intervals by assessing how new data points conform to the distribution of the training data, providing robust interval estimates that are valid under minimal assumptions.

The Random Forest with conformal intervals achieved a 95% confidence level. Visualizations highlighted the actual values alongside predictions and interval bounds, with a mean absolute error (MAE) of 0.42 and a prediction interval coverage probability of 92.2%, indicating reliable performance but slight under-coverage in some regions. The uniformity in interval widths across different regions of the target values reflects consistent interval estimation, though some deviations were observed at data extremes.

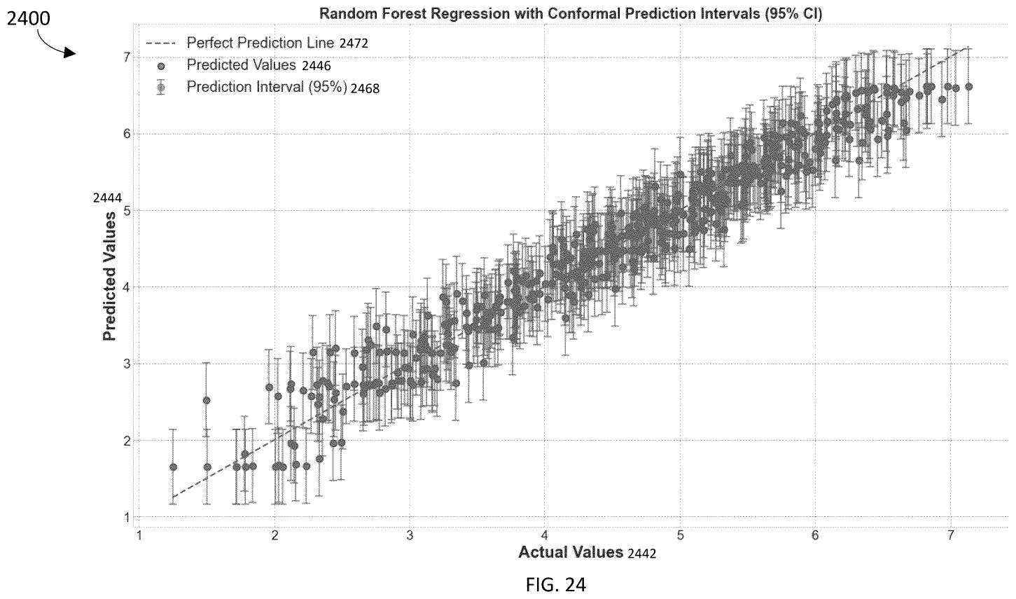

FIG. 23 is a plot 2300 of conformal prediction intervals for target value 2342 versus sample index 2362 with random forest regressor model results on a subset of the test synthetic 2D FEM data of FIG. 16.

In an embodiment, the plot 2300 shows the results of a Random Forest regressor with conformal prediction intervals on a subset of the test data. The line 2364 with circle markers represents the actual target values, while the dashed line 2346 with ‘x’ markers corresponds to the model's predictions. The shaded area 2366 around the predictions 2346 indicates the 95% confidence interval (CI) generated using conformal prediction. The intervals 2366 illustrate the uncertainty around each prediction 2346, and their varying width reflects how confident the model is for different samples 2362.

In FIG. 23, most actual values 2364 fall within the shaded intervals, indicating that the conformal intervals 2366 are valid and reliable. The MAE is 0.42, and the model achieved an accuracy of 89.63%, suggesting a good fit but with some deviation in certain regions where actual values 2364 lie closer to the edges or outside the intervals 2366. The wider intervals 2366 in some segments indicate higher uncertainty in those predictions 2346, possibly due to limited data or more complex relationships in the target values 2342.

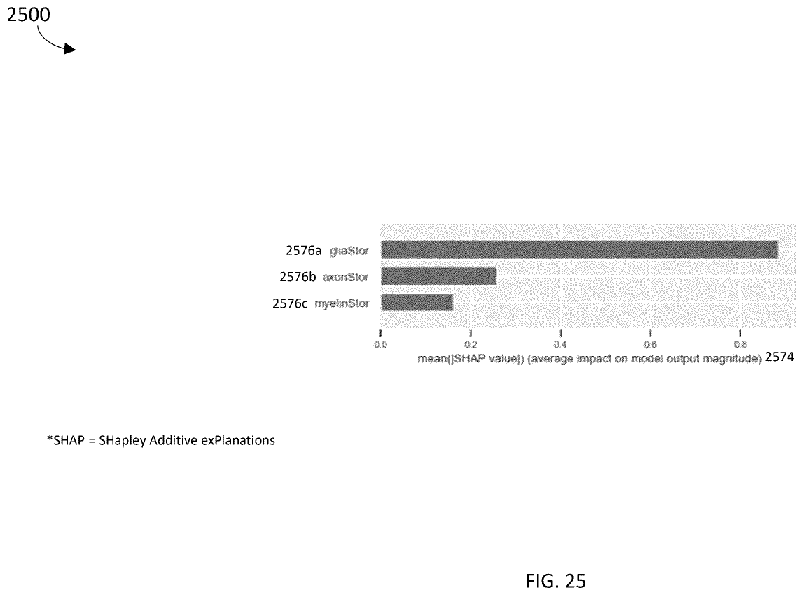

FIG. 24 is a plot 2400 of random forest regression results with conformal prediction intervals (predicted values 2444 versus actual values 2442) according to an example embodiment.

The plot 2400 shows the Random Forest regression results with conformal prediction intervals 2468 using a 95% CI. The error bars around each predicted point 2446 represent the interval estimates 2468, while the dashed line 2472 indicates the perfect prediction line. The Prediction Interval Coverage is 0.922, indicating that approximately 92.2% of actual values 2442 fall within the conformal intervals 2468. This is slightly below the expected 95%, suggesting some minor undercoverage, but overall, the intervals 2468 capture most of the true values.

### Example Comparison to Quantile Regression Prediction Intervals

Quantile regression offers adaptive prediction intervals that adjust to local data variability, making it particularly effective for datasets with heteroscedasticity. The intervals tend to narrow around central regions and widen at the distribution tails, providing nuanced insights into local uncertainty patterns. However, quantile regression can sometimes struggle to maintain coverage at the tails, especially if the model is not well-calibrated for these cases.

In contrast, conformal prediction intervals are generally more uniform and model-agnostic, ensuring reliable interval coverage regardless of the underlying model or data distribution. This method guarantees finite-sample coverage, making it robust for new and unseen data points. While conformal intervals may lack the flexibility of quantile regression in capturing fine-grained local variability, they provide more reliable and consistent interval estimates for general use.

Thus, conformal prediction intervals are more trustworthy when generalizing to new data, as they ensure interval coverage without requiring assumptions about data distribution. Quantile intervals, while accurate for well-distributed and balanced datasets, may not perform as well for new or outlier cases, making them less reliable for edge scenarios.

Summary from Example Prediction Interval Analysis

The conformal method is advantageous for robust, model-agnostic uncertainty estimation across a variety of scenarios, ensuring reliable performance and valid interval coverage. Quantile regression, on the other hand, offers greater flexibility and adaptiveness to local data characteristics, making it suitable for datasets with complex variance structures. Thus, the choice between these methods depends on the application: conformal intervals are ideal for ensuring trustworthy predictions in diverse settings, while quantile regression is more effective for capturing detailed uncertainty patterns in well-behaved datasets.

### Example Hyper-Parameter Optimization

In an embodiment, hyper-parameter optimization (HPO) was carried out for various machine learning models to improve predictive accuracy and ensure optimal performance. The optimization techniques employed included Grid Search Cross-Validation (CV), which systematically evaluates combinations of hyper-parameters by training and validating each model using five-fold cross-validation. For each model—MLP Regressor, Random Forest Regressor, GBDT, and Linear Regression—a predefined hyper-parameter space was constructed based on key tuning parameters relevant to the respective models.
MLP Regressor was tuned for the number of hidden layers, activation functions, learning rates, and solvers, aiming to find the architecture that balances learning capacity and computational efficiency.
Random Forest hyper-parameters such as the number of estimators, maximum tree depth, and the maximum number of features considered for splitting were optimized to reduce overfitting and enhance generalization.
GBDT parameters such as learning rate, number of boosting stages, and subsample ratio were adjusted to capture complex interactions while minimizing model complexity.
Linear Regression was optimized for different learning rates and iterations, ensuring convergence of the optimization algorithm.

According to an embodiment, the GridSearchCV method was used to identify the best hyper-parameters based on MSE, MAE, and RMSE. The optimal parameters were selected based on performance on a separate validation set, and the models were retrained using these configurations. This process ensured that the final models were tuned for maximum predictive performance, providing a robust foundation for comparative analysis.

TABLE 2
Summary of example HPO results on predictive ML/AI models in predictive ML/AI
workflow pipeline.

| | | | | Results | |
|---|---|---|---|---|---|
| | | | | (Accuracy % | |
| | | | | and other metrics) | |
| Regression | Default | Best HPO | Optimized param | Before | After |
| ML Models | parameter space | method | space | HPO | HPO |
| Linear | ′copy_X′: True, | Hyperopt | ′fit_intercept′: 0 | MSE: | MSE: |
| Regression | ′fit_intercept′: True, | | | 0.0749, | 0.0753, |
| | ′n_jobs′: None, | | | RMSE: | RMSE: |
| | ′normalize′: | | | 0.2737, | 0.2745, |
| | ′deprecated′, | | | R2 | R2 |
| | ′positive′: False | | | Score: | Score: |
| | | | | 0.9531 | 0.9528 |
| MLP | max_iter=500, | Hyperopt | ′activation′: 0, ′alpha′: | MSE: | MSE: |
| Regressor | random_state=1 | | 0.09281512089160027, | 0.0212, | 0.0198, |
| | | | ′hidden_layer_sizes′: 0, | RMSE: | RMSE: |
| | | | ′solver′: 0 | 0.1456, | 0.1406 , |
| | | | | R2 | R2 |
| | | | | Score: | Score: |
| | | | | 0.9867 | 0.9876 |
| Random | max_depth=2, | GridSearchCV | ′max_depth′: 100, | R2 | R2 |
| Forest | random_state=0) | | ′max_features′: ′auto′, | Score: | Score: |
| (RF) | | | ′min_impurity_decrease′: | 0.8967 | 0.9829 |
| | | | 0.0, ′min_samples_leaf′: | | |
| | | | 1, ′min_samples_split′: 2, | | |
| | | | ′min_weight_fraction_ | | |
| | | | leaf′: 0.0, ′n_estimators′: | | |
| | | | 100, ′n_jobs′: 1 | | |
| GBDT | alpha′: 0.9, | Hyperopt | ′learning_rate′: | MSE: | MSE: |
| | ′ccp_alpha′: 0.0, | | 0.11249245049802054, | 0.0258, | 0.0248, |
| | ′criterion′: | | ′max_depth′: 3.0, | RMSE: | RMSE: |
| | ′friedman_mse′, | | ′min_samples_split′: 7.0, | 0.1606, | 0.1575, |
| | ′init′: None, | | ′n_estimators′: 170. | R2 | R2 |
| | ′learning_rate′: 0.1, | | | Score: | Score: |
| | ′loss′: | | | 0.9839 | 0.9845 |
| | ′squared_error′, | | | | |
| | ′max_depth′: 3, | | | | |
| | ′max_features′: | | | | |
| | None, | | | | |
| | ′max_leaf_nodes′: | | | | |
| | None, | | | | |
| | min_impurity_ | | | | |
| | decrease′: 0.0, | | | | |
| | ′min_samples_leaf′: | | | | |
| | 1, | | | | |
| | ′min_samples_split′: | | | | |
| | 2, | | | | |
| | ′min_weight_ | | | | |
| | fraction_leaf′: 0.0, | | | | |
| | ′n_estimators′: 100, | | | | |
| | ′n_iter_no_change′: | | | | |
| | None, | | | | |
| | ′random_state′: 0, | | | | |
| | ′subsample′: 1.0, | | | | |
| | tol′: 0.0001, | | | | |
| | ′validation_fraction′: | | | | |
| | 0.1, ′verbose′: 0, | | | | |
| | ′warm_start′: False | | | | |
| Light | ′boosting_type′: | Hyperopt | ′learning_rate′: | MSE: | MSE: |
| GBM | ′gbdt′, ′class_weight′: | | 0.10705975491341019, | 0.0263, | 0.0243, |
| | None, | | ′max_depth′: 2.0, | RMSE: | RMSE: |
| | ′colsample_bytree′: | | ′n_estimators′: 300.0, | 0.1622, | 0.1560, |
| | 1.0, | | ′num_leaves′: 130.0 | R2 | R2 |
| | ′importance_type′: | | | Score: | Score: |
| | ′split′, | | | 0.9835 | 0.9848 |
| | ′learning_rate′: 0.1, | | | | |
| | ′max_depth′: −1, | | | | |
| | ′min_child_samples′: | | | | |
| | 20, | | | | |
| | ′min_child_weight′: | | | | |
| | 0.001, | | | | |
| | ′min_split_gain′: 0.0, | | | | |
| | ′n_estimators′: 100, | | | | |
| | ′n_jobs′: −1, | | | | |
| | ′num_leaves′: 31, | | | | |
| | ′objective′: None, | | | | |
| | ′random_state′: | | | | |
| | None, ′reg_alpha′: | | | | |
| | 0.0, ′reg_lambda′: | | | | |
| | 0.0, ′silent′: ′warn′, | | | | |
| | ′subsample′: 1.0, | | | | |
| | ′subsample_for_bin′: | | | | |
| | 200000, | | | | |
| | ′subsample_freq′: 0 | | | | |

Table 2 above clearly outlines the benefit of implementing HPO, especially on complex regression models to optimize model performance. From the HPO methods it is seen that Hyperopt is the fastest in execution time while GridSearchCV takes longer (random search logic). Likewise, Bayesian search required longer computation time and often not the best HPO model. Thus, a modular HPO function is able to test each predictive ML/AI model architecture on an ensemble of HPO methods to yield the best parameters and HPO improved model output metrics.

MLP Regressor emerged as best overall model while HPO showed biggest improvement for RF model.

### Example Model Interpretability and Explainability

In an embodiment, to enhance the interpretability of the ML/AI models, SHAP was used to provide insights into feature importance and the impact of each feature on model predictions. SHAP values quantify the contribution of each feature to the prediction output by computing the average contribution of a feature across different coalitions of features. The SHAP analysis was applied using the TreeExplainer method for tree-based models, and several visualization techniques were utilized to interpret model behavior.
Dependence Plot: The dependence plot was used to visualize the relationship between a specific feature and its SHAP values, indicating how changes in the feature's values influence the model output. This plot helps identify feature interactions and non-linear dependencies.
Force Plot: A force plot was generated for individual predictions to show the cumulative effect of each feature (positive or negative) in pushing the prediction away from the model's expected baseline value. This helps explain why a particular prediction was made for a given instance.
Summary Plot: A SHAP summary plot was used to visualize the overall impact of all features across the dataset, ranking them by their importance and showing the distribution of their influence. This plot helps identify the most critical features contributing to the model's predictions.

These visualizations provide a comprehensive understanding of model behavior, helping to ensure that the models are not only accurate but also transparent and interpretable.

### Example SHAP Analysis—Results

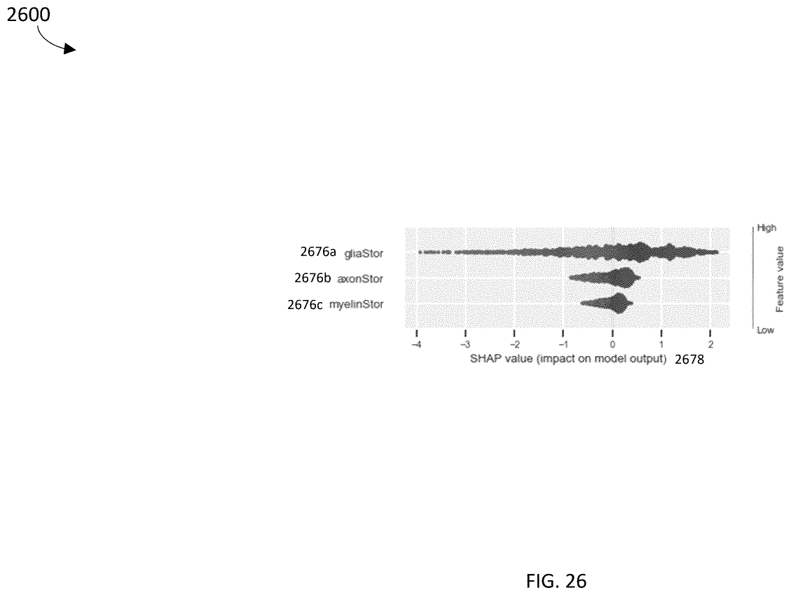

FIG. 25 is a bar plot 2500 showing mean absolute SHAP values 2574 for feature 2576a-2576c importance according to an example embodiment. As shown in FIG. 25, the plot 2500 indicates the average impact 2574 of each feature 2576a-2576c on the model's output.

A comprehensive SHAP analysis is presented to interpret the predictive model for BWM VE properties. FIG. 25 shows that gliaStor 2576a has the highest average impact 2574 on the model's predictions, followed by axonStor 2576b and myelinStor 2576c.

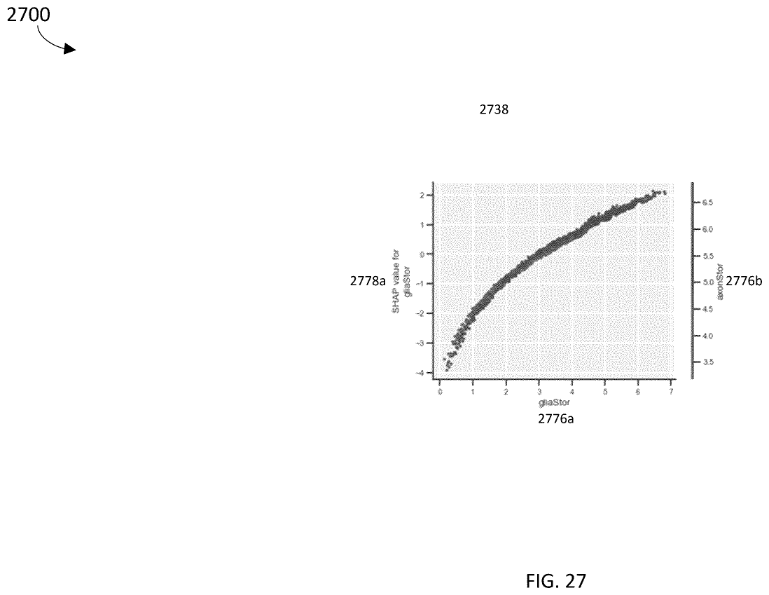

FIG. 26 is a summary plot 2600 of SHAP values 2678 for individual predictions according to an example embodiment. In the plot 2600, colors represent feature 2676a-2676c values with red for high and blue for low.

FIG. 26 shows the distribution of SHAP values for each feature 2676a-2676c, revealing how high and low feature values affect the model output.

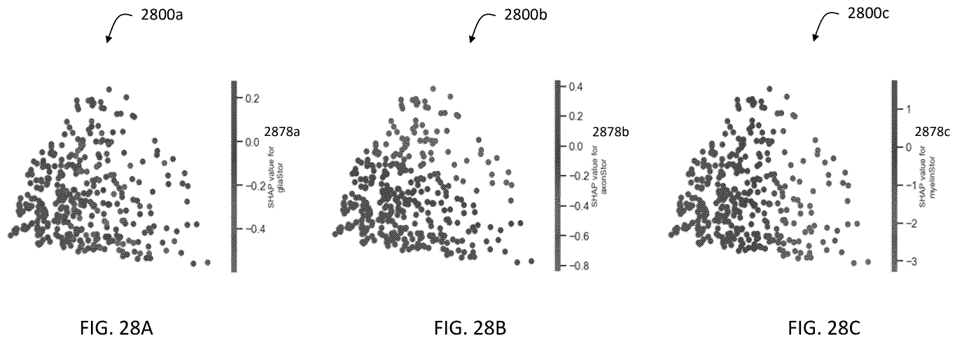

FIG. 27 is a dependence plot 2700 illustrating a relationship between a gliaStor feature 2776a and its SHAP values 2778a according to an example embodiment. The plot 2700 highlights interactions of the gliaStor feature with other features, e.g., axonStor 2776b using a color scale.

The dependence plot 2700 for gliaStor 2776a is shown in FIG. 27, indicating a positive relationship with the prediction and interactions with other features, e.g., axonStor 2776b.

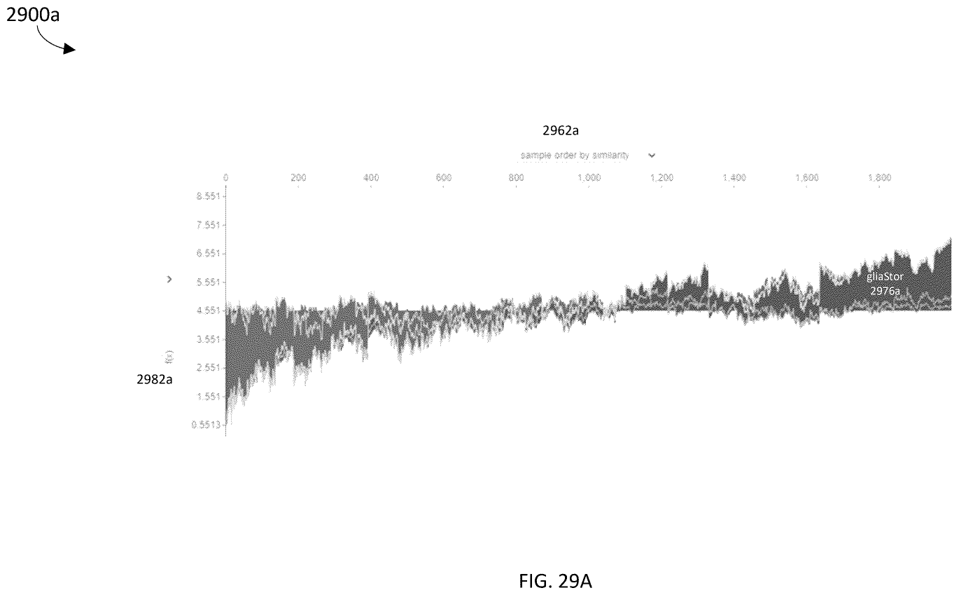

FIGS. 28A-28C are embedding plots 2800a-2800c, respectively, showing a distribution of color-coded SHAP values 2878a-2878c according to an example embodiment. In an embodiment, the plots 2800a-2800c visualize feature-specific contributions.

The embedding plots 2800a-2800c in FIGS. 28A-28C are presented for gliaStor, axonStor, and myelinStor, respectively, highlighting how each feature's values influence their respective SHAP values and contribute to the model's output. These visualizations provide valuable insights into feature importance, individual feature impacts, and interactions within the ML/AI model.

### Example Summary Plot

The SHAP summary plot in bar chart form 2500 (FIG. 25) displays the average impact 2574 of each feature 2576a-2576c on the model output (homogenized storage modulus). The x-axis 2574 represents the mean absolute SHAP values, which indicate the magnitude of each feature's 2576a-2576c contribution to the model's predictions. Higher SHAP values suggest a greater influence on the model's output. Following key observations are made:
gliaStor 2576a has the highest SHAP value, indicating that this feature has the most significant impact on the model's predictions compared to other features.
axonStor 2576b has a moderate impact, contributing less than gliaStor 2576a but more than the other feature 2576c.
myelinStor 2576c has the lowest SHAP value among the three features 2576a-2576c, suggesting it is the least influential.

In an embodiment, a summary plot chart, e.g., 2500, provides a straightforward way to rank feature importance, helping to understand which features the model relies on most for making predictions. This type of visualization is beneficial for identifying key predictors and understanding the model's behavior in a clear and interpretable manner.

### Example Directionality Impact Plot

The SHAP summary plot uses a dot chart 2600 (FIG. 26) to illustrate the directionality and impact of each feature 2676a-2676c on the model output. Each point in the plot 2600 represents a SHAP value for a particular feature 2676a-2676c in a single observation, and the x-axis 2678 shows the SHAP values, indicating the direction and magnitude of each feature's 2676a-2676c effect on the model's prediction. The directionality plot 2600 effectively visualizes how feature 2676a-2676c values influence the model output, providing insights into not only the importance but also the directionality of each feature's 2676a-2676c effect on the prediction. Key observations:

### Color Coding.

The color of each dot reflects the feature 2676a-2676c value, with red indicating high values and blue indicating low values, as shown in FIG. 26.

### Interpretation of SHAP Values

Positive SHAP values 2678 (to the right of 0) push the model prediction higher, while negative SHAP values 2678 (to the left of 0) push the prediction lower.

### Feature Impact and Directionality

For gliaStor 2676a, high values (in red) are associated with a positive impact on the model's prediction of “homogenized storage modulus”, while low values (in blue) have a negative impact.
For axonStor 2676b and myelinStor 2676c, the distribution of SHAP values 2678 suggests that the directionality is more nuanced, with high values pushing the prediction in both directions depending on the instance.

### Example Dependence Plot

The SHAP dependence plot 2700 (FIG. 27) is used to visualize the effect of a single feature (gliaStor 2776a) on the model's prediction. Each point represents a single prediction from the dataset, with the x-axis 2776a showing the actual feature values and the y-axis 2778a representing the corresponding SHAP values, which indicate the feature's 2776a impact on the model output. The color of the points shows the value of an interacting feature (axonStor 2776b), helping to identify interactions between features.

It is observed that as gliaStor 2776a increases, the SHAP value 2778a also increases, indicating a positive relationship with the model's prediction. The dependence plot 2700 is useful for detecting non-linear relationships and interactions between features, as highlighted by the smooth upward trend and the impact of axonStor 2776b values. This concise representation helps in understanding how changes in gliaStor 2776a influence the model's predictions, while also showing how its impact is moderated by another feature (axonStor 2776b).

### Example Force Plot

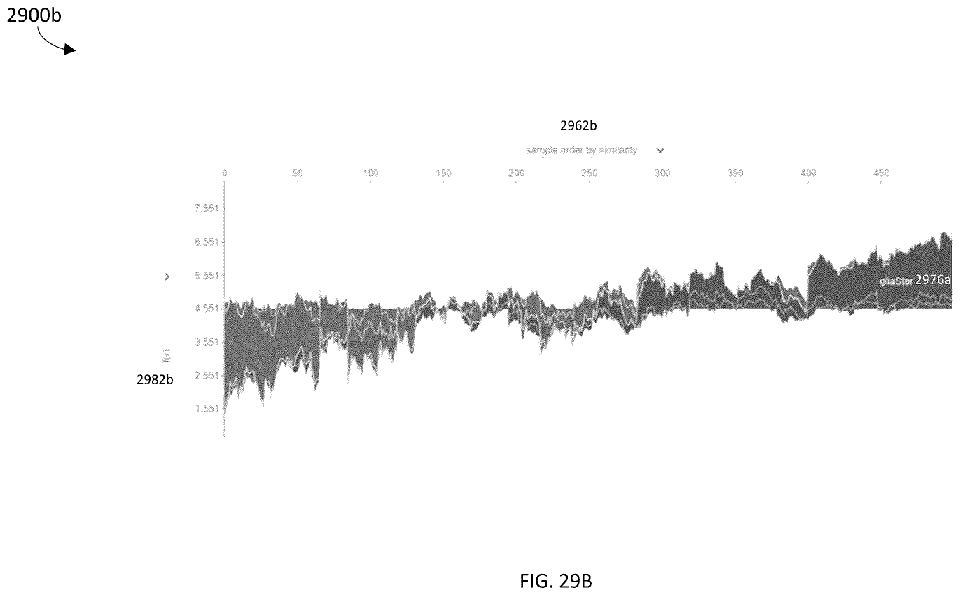

FIGS. 29A and 29B are SHAP force plots 2900a and 2900b on training set and test set data, respectively, according to an example embodiment.

The SHAP force plots 2900a and 2900b are used to explain the overall contribution of features for a set of predictions 2982a and 2982b, respectively, in both the training and test datasets. Each horizontal line represents a single prediction, where the x-axes 2962a and 2962b list the different samples, ordered by similarity.

### Color Coding

Features contributing positively to the model's prediction (increasing the output) are shown in red in FIGS. 29A and 29B, while features pushing the prediction lower are shown in blue.

### Cumulative Impact.

The width of the red and blue segments indicates the strength of the contribution, with the net effect determining the final prediction for each sample.

### Consistency in Training Versus Testing

The pattern of contributions is relatively consistent between the training and test sets, suggesting stability in feature influence, e.g., gliaStor 2976a is prominently influencing predictions 2982a and 2982b in both plots 2900a and 2900b, respectively. These force plots 2900a and 2900b provide a visual summary of how different features collectively influence each prediction, helping to analyze both global and local model behavior.

### Example Waterfall Plot

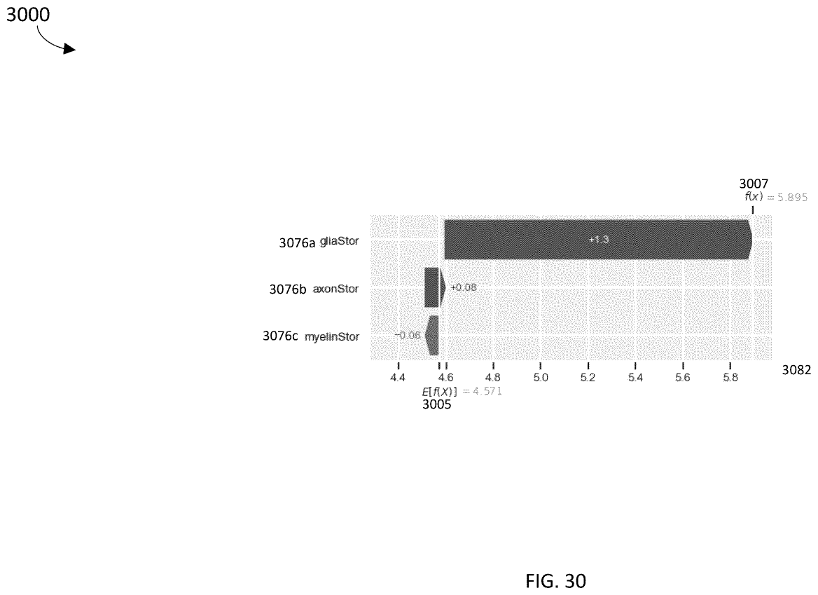

FIG. 30 is a waterfall plot 3000 visualizing individual features' 3076a-3076c contributions to a single prediction 3082 according to an example embodiment. In an embodiment, the plot 3000 starts from the predictive ML/AI model's baseline (average prediction) and displays how each feature 3076a-3076c value shifts the prediction 3082 higher or lower.

The SHAP waterfall plot 3000 visualizes how individual features 3076a-3076c contribute to a single prediction, starting from the model's baseline (average prediction) and displaying how each feature 3076a-3076c value shifts the prediction higher or lower. Each bar 3076a-3076c in the plot 3000 represents a feature's contribution, either positive contributions that increase the model's output or negative contributions that decrease it (i.e., homogenized storage modulus).

The baseline value 3005 (expected value, E[f(x)]) starts at 4.571 on the x-axis 3082. In FIG. 30, the prediction value 3007 for this specific sample is 5.895 (f(x)), achieved through the cumulative impact of the three features (gliaStor 3076a, axonStor 3076b, and myelinStor 3076c).

gliaStor 3076a has the largest positive contribution (+1.3), significantly increasing the prediction value 3007. axonStor 3076b and myelinStor 3076c have minor impacts, with axonStor 3076b contributing slightly positively (+0.08) and myelinStor 3076c contributing slightly negatively (−0.06). The waterfall plot 3000 effectively demonstrates the direction and magnitude of each feature's 3076a-3076c effect, providing an intuitive breakdown of how the final prediction 3007 is constructed from the baseline 3005.

### Example Embedding Plot

SHAP embedding plots 2800a-2800c are depicted in FIGS. 28A-28C for three different features: gliaStor, axonStor, and myelinStor, respectively. Each plot 2800a-2800c visualizes the SHAP values of a specific feature to represent its contribution to the model's predictions. The embedding plots 2800a-2800c provide an intuitive way to analyze how individual features contribute to predictions across different samples, making it easier to identify patterns and interpret feature significance in the model. In the embedding plots, red color indicates high SHAP values, meaning the feature has strong positive influence on predicted value of homogenized storage modulus (target variable). On the other hand, blue indicates low SHAP values, reflecting a negative influence on the prediction.
The plot 2800a shows the SHAP values 2878a for gliaStor. A clear clustering pattern is visible, indicating distinct impacts on prediction depending on gliaStor values.
The plot 2800b depicts SHAP values 2878b for axonStor. The distribution of colors suggests varying degrees of influence, but the overall impact is less pronounced compared to gliaStor.
The plot 2800c represents myelinStor, where the SHAP values 2878c are comparatively lower, suggesting this feature has a weaker influence on the model's output.

### Example Tissue Sensitivity Analysis

From the SHAP plots, it is clear that effective storage moduli (i.e., homogenized storage modulus) is sensitive to the glia storage, axon storage, and myelin storage moduli. This is in line with the prior sensitivity analysis findings, which also revealed that effective moduli are very sensitive to the intrinsic loss and storage moduli of the glia along with fiber volume fraction.

In an embodiment, a forward ML/AI model in conjunction with results from prior sensitivity analysis can help connect the effective VE moduli property of the perfect solution of the (anisotropic) inverse problem with WM microarchitecture and intrinsic properties of its constituents phases.

### Computer Support

FIG. 31 is a schematic view of a computer network in which embodiments may be implemented.

Client computer(s)/devices 50 and server computer(s) 60 provide processing, storage, and input/output (I/O) devices executing application programs and the like. Client computer(s)/device(s) 50 can also be linked through communications network 70 to other computing devices, including other client device(s)/processor(s) 50 and server computer(s) 60. Communications network 70 can be part of a remote access network, a global network (e.g., the Internet), cloud computing servers or service, a worldwide collection of computers, local area or wide area networks, and gateways that currently use respective protocols (e.g., TCP/IP, Bluetooth®, etc.) to communicate with one another. Other electronic device/computer network architectures are suitable.

FIG. 32 is a block diagram illustrating an example embodiment of a computer node (e.g., client processor(s)/device(s) 50 or server computer(s) 60) in the computer network of FIG. 31. Each computer node 50, 60 contains system bus 79, where a bus is a set of hardware lines used for data transfer among components of a computer or processing system. The bus 79 is essentially a shared conduit that connects different elements of a computer system (e.g., processor, disk storage, memory, I/O ports, network ports, etc.) that enables transfer of information between the elements. Attached to the system bus 79 is I/O device interface 82 for connecting various input and output devices (e.g., keyboard, mouse, display(s), printer(s), speaker(s), etc.) to the computer node 50, 60. A network interface 86 allows the computer node to connect to various other devices attached to a network (e.g., network 70 of FIG. 31). A memory 90 provides volatile storage for computer software instructions 92a and data 94a used to implement an embodiment of the present disclosure (e.g., the process 100, the method 200, the process 300, the process 400, the method 500, the process 700, the process 800a, the process 800b, the process 1400, and the workflow 1700 described hereinabove with respect to FIGS. 1, 2, 3, 4, 5, 7, 8A, 8B, 14, and 17, respectively). A disk storage 95 provides non-volatile storage for the computer software instructions 92b and data 94b used to implement an embodiment of the present disclosure. A central processor unit 84 is also attached to the system bus 79 and provides for execution of computer instructions.

In one embodiment, the processor routines 92a-92b and data 94a-94b are a computer program product (generally referenced as 92), including a computer readable medium (e.g., a removable storage medium such as DVD-ROM(s), CD-ROM(s), diskette(s), tape(s), etc.) that provides at least a portion of the software instructions for the disclosure system. Computer program product 92 can be installed by any suitable software installation procedure, as is well known in the art. In another embodiment, at least a portion of the software instructions may also be downloaded over a cable, communication, and/or wireless connection. In other embodiments, the disclosure programs are a computer program propagated signal product embodied on a propagated signal on a propagation medium (e.g., a radio wave, an infrared wave, a laser wave, a sound wave, or an electrical wave propagated over a global network such as the Internet, or other network(s)). Such carrier medium or signals provide at least a portion of the software instructions for the present disclosure routines/program 92.

In alternate embodiments, the propagated signal is an analog carrier wave or digital signal carried on the propagated medium. For example, the propagated signal may be a digitized signal propagated over a global network (e.g., the Internet), a telecommunications network, or other network (such as network 70 of FIG. 31). In one embodiment, the propagated signal is a signal that is transmitted over the propagation medium over a period of time, such as the instructions for a software application sent in packets over a network over a period of milliseconds, seconds, minutes, or longer. In another embodiment, the computer readable medium of the computer program product 92 is a propagation medium that the computer system 50 may receive and read, such as by receiving the propagation medium and identifying a propagated signal embodied in the propagation medium, as described above for computer program propagated signal product.

Generally speaking, the term “carrier medium” or transient carrier encompasses the foregoing transient signals, propagated signals, propagated medium, storage medium, and the like.

In other embodiments, the program product 92 may be implemented as a so-called Software as a Service (SaaS), or other installation or communication supporting end-users.

### Example Scripted Electrical Type Data

Provided hereinbelow as Appendix A is example pseudo code for scripting electrical type data, e.g., for the input type 103 (FIG. 1) or 303 (FIG. 3). In an embodiment, a scripted program or other programming code may be created to perform a multi-physics simulation in, e.g., Abaqus (such as Python scripting/subroutine creation), whereby BWM is modeled as an RVE for a forward model phase, e.g., the forward process 100 (FIG. 1) or 300 (FIG. 3).

Referring to Appendix A, in an embodiment, in the case of soft tissue or composite RVEs, axon fibers (neurons) may be modeled as cylindrical fibers or inclusions embedded in an ECM (e.g., glia phase). Next, synaptic connections in neurons may be depicted by modeling linkages (e.g., line or beam geometries or other relevant element types) to connect the axonal fibers. To achieve this web of connections, the fiber connection networks may be formulated using a graph theory approach.

Referring again to Appendix A, in an embodiment, a graph theory code function (e.g., a class in Python or similar scripting language) may generate a stochastic connection or network of neural linkages, which behaves as a path or circuits for electrical potential and/or impulse transfer and an FEM boundary condition in a multi-physics model may be applied to these geometries for electrical physics simulation. This hybrid geometry setup may accomplish the task of simulating mechano-electrical properties for brain matter (as an example of soft composites).

The example pseudo code in Appendix A includes the following functionality, for non-limiting examples:
a) Defining classes for AxonFiber and Graph to represent axonal fibers and their connections.
b) Implementing a generate_axon_fibers( ) function to generate axon fibers and their positions.
c) Creating a graph representing the network of axonal fibers.
d) Populating the graph with nodes (axon fibers) and their connections based on desired criteria (e.g., proximity).
e) Applying electrical boundary conditions to nodes and connectivity between nodes based on the graph connections.
f) Executing the main script to build the axonal network and apply electrical boundary conditions.
g) The functions generate_axon_fibers( ), calculate_distance( ), apply_electrical_condition( ), and apply_connectivity( ) may optionally be replaced with implementations suited for a particular simulation and/or environment (e.g., Abaqus). This may optionally be integrated with an existing workflow for compatibility and/or simulation setup purposes.
h) Implementing a save_graph_to_file( ) function that saves the axonal network graph to a JavaScript® Object Notation (JSON) file or other suitable known format.
i) Implementing a build_connected_graph( ) function to modify the graph to ensure that each node has at least, e.g., six, and at most, e.g., 80, connections by shuffling and selecting a subset of connections for each node.
j) Specifying that the main script saves the modified graph to a file named axon_network_graph.json.

Embodiments or aspects thereof may be implemented in the form of hardware including but not limited to hardware circuitry, firmware, or software. If implemented in software, the software may be stored on any non-transient computer readable medium that is configured to enable a processor to load the software or subsets of instructions thereof. The processor then executes the instructions and is configured to operate or cause an apparatus to operate in a manner as described herein.

Further, hardware, firmware, software, routines, or instructions may be described herein as performing certain actions and/or functions of the data processors. However, it should be appreciated that such descriptions contained herein are merely for convenience and that such actions in fact result from computing devices, processors, controllers, or other devices executing the firmware, software, routines, instructions, etc.

It should be understood that the flow diagrams, block diagrams, and network diagrams may include more or fewer elements, be arranged differently, or be represented differently. But it further should be understood that certain implementations may dictate the block and network diagrams and the number of block and network diagrams illustrating the execution of the embodiments be implemented in a particular way.

Accordingly, further embodiments may also be implemented in a variety of computer architectures, physical, virtual, cloud computers, and/or some combination thereof, and, thus, the data processors described herein are intended for purposes of illustration only and not as a limitation of the embodiments.

The teachings of all patents, published applications, and references cited herein are incorporated by reference in their entirety. The contents of the Appendices are incorporated herein by reference in their entirety.

While example embodiments have been particularly shown and described, it will be understood by those skilled in the art that various changes in form and details may be made therein without departing from the scope of the embodiments encompassed by the appended claims.

### REFERENCES

[1] Wu, Xuehai, John G. Georgiadis, and Assimina A. Pelegri. “Biphasic Representative Elemental Volumes for 3-D White Matter Elastography.” In ASME International Mechanical Engineering Congress and Exposition, vol. 85598, p. V005T05A039. American Society of Mechanical Engineers, 2021.
[2] Wu, Xuehai, and Assimina A. Pelegri. “Deep 3D convolution neural network methods for brain white matter hybrid computational simulations.” In ASME International Mechanical Engineering Congress and Exposition, vol. 84522, p. V005T05A002. American Society of Mechanical Engineers, 2020.
[3] Wu, Xuehai, John G. Georgiadis, and Assimina A. Pelegri. “Harmonic viscoelastic response of 3D histology-informed white matter model.” Molecular and Cellular Neuroscience 123 (2022): 103782.
[4] Agarwal, Mohit, Parameshwaran Pasupathy, Robert De Simone, and Assimina A. Pelegri. “Oligodendrocyte tethering effect on hyperelastic 3D response of injured axons in brain white matter.” In ASME International Mechanical Engineering Congress and Exposition, vol. 85598, p. V005T05A050. American Society of Mechanical Engineers, 2021.
[5] Gladkov, Arseniy, et al., “Design of cultured neuron networks in vitro with predefined connectivity using asymmetric microfluidic channels.” Scientific reports 7.1 (2017): 15625.
[6] Baltrušaitis, Tadas, et al., “Multimodal machine learning: A survey and taxonomy.” IEEE transactions on pattern analysis and machine intelligence 41.2 (2018): 423-443.
[7] Ngiam, Jiquan, et al., “Multimodal deep learning.” Proceedings of the 28^{th} international conference on machine learning (ICML-11). 2011.
[8] Destrade, Michel, et al., “Extreme softness of brain matter in simple shear.” International Journal of Non-Linear Mechanics 75 (2015): 54-58.
[9] Zurlo, Giuseppe, et al., “The Poynting effect.” American Journal of Physics 88.12 (2020): 1036-1040.
[10] Agarwal, Mohit, John Georgiadis, and Assimina A. Pelegri, “Deep Neural Network Driven Hybrid Simulations to Evaluate Poynting Effect in Ogden Hyperelastic 3D Brain White Matter,” 2024, forthcoming.
[11] Agarwal, Mohit, John Georgiadis, and Assimina A. Pelegri, “Data-Driven Depiction of Aging Related Physiological Volume Shrinkage in Brain White Matter: An Image Processing Based Three-Dimensional Micromechanical Model.” Journal of Engineering and Science in Medical Diagnostics and Therapy 8, No. 4 (2025).
[12] Ashish Bhan, et al., “A duplication growth model of gene expression networks,” Bioinformatics, Volume 18, Issue 11, November 2002, Pages 1486-149.
[13] N. Dhulekar et al., “Prediction of Growth Factor-Dependent Cleft Formation During Branching Morphogenesis Using A Dynamic Graph-Based Growth Model,” in IEEE/ACM Transactions on Computational Biology and Bioinformatics, vol. 13, no. 2, pp. 350-364, 1 Mar.-Apr. 2016, doi: 10.1109/TCBB.2015.2452916.
[14] Quentin Duchemin, et al., “Markov random geometric graph, MRGG: A growth model for temporal dynamic networks,” Electron. J. Statist. 16(1), 671-699, (2022).
[15] Agarwal, Mohit, and Assimina A. Pelegri. “Numerical Simulation of Stress States to Evaluate Oligodendrocyte Tethering Effect on Hyperelastic 3D Response of Injured Axons in Brain White Matter.” Diss. Rutgers The State University of New Jersey, School of Graduate Studies, 2022.

APPENDIX A
Example Pseudo Code for Scripting Electrical Type Data

```
## import all libraries from Abaqus
import abaqus
import argparse
import copy
import logging
import os
import shutil
import sys
import tempfile
from abaqusConstants import COPLANAR_EDGES
from logging.config import dictConfig
from math import pi
from os import path
from pprint import pformat
from time import sleep
import numpy as np
from abaqus import openMdb
from helpers import cd, get_log_config
from persistqueue import FIFOSQLiteQueue
## create geometries first
## class Axon fiber
## creates geometry of coated/uncoated axon/neuronal fibers
class AxonFiber:
  def _{——}init_{——}(self, id, position, radius):
      self.id = id
      self.position = position
      self.radius = radius
## define material properties
## Code functions for definition of material properties
## define both mechanical and electrical properties in workflow
## define interactions between graph elem. beams/RVE geometries
def interaction_graph_axon(axon, graph, tuning parameters):
  ## give axon and graph geometry
  ## create dictionary of connection/interaction types
  ## the dictionary approach is a novel/modular approach to
  ## experiment all interaction types between the graph and
  ## composite geometry - see sample dictionary below:
  Interaction_options = {‘1’: , ‘2’: }
    ## tuning parameters determine how dense the graph and
    ## geometry interaction should be
    ## the tuning parameter behaves as a regularizing parameter
## code the function that generates the graph of connections
class Graph:
  def _{——}init_{——}(self):
      self.nodes = { } ## Dict. stores nodes/their connections
  def add_node(self, node_id, connections):
      self.nodes[node_id] = connections
  def add_connection(self, node_id, connection):
      if node_id in self.nodes:
        self.nodes[node_id].append(connection)
      else:
        self.nodes[node_id] = [connection]
## there are many methods to model graph -
## uni directed graphs, binary tree method type, balanced graph,
## unbalanced graph, random graphs, parametric graph, and
## best path / density graph, etc.
## add constraints in the graph definition to ensure min.
## number of connecting links and max. number of connecting
## links. The oligodendrocyte literature says the range at each
## node will be in range of 6 to 80.
Range_of_node_connections = [6:80]
def build_axonal_network( ):
  ## generate axon fibers and their positions
  axon_fibers = generate_axon_fibers( )
  ## Create a graph to represent the network
  axonal_graph = Graph( )
  ## Populate the graph with axon fibers and their connections
  for axon_fiber in axon_fibers:
      axonal_graph.add_node(axon_fiber.id, [ ])
      ## Add connections to axon fiber based on desired
      ## criteria, e.g., proximity
      for other_fiber in axon_fibers:
        if axon_fiber != other_fiber:
          distance =
calculate_distance(axon_fiber.position, other_fiber.position)
          if distance < threshold:
            axonal_graph.add_connection(axon_fiber.id,
other_fiber.id)
  return axonal_graph
## once the fiber geometry and electrical connection geometries
## are obtained, apply electrical boundary conditions (B.C.s)
def apply_electrical_boundary_conditions(axonal_graph):
  ## Apply electrical B.C.s based on graph connections
  for node_id, connections in axonal_graph.nodes.items( ):
      ## apply electrical conditions to nodes
      apply_electrical_condition(node_id)
      for connection_id in connections:
        ## apply connectivity between nodes
        apply_connectivity(node_id, connection_id)
## Save graph connection as a file - this file can be leveraged
## later in a hybrid workflow to define a NumPy array for
## an electrical modal input type channel in a composite forward
## pass model.
def save_graph_to_file(axonal_graph, filename):
  with open(filename, ‘w’) as file:
      json.dump(axonal_graph.nodes, file)
## The code snippet below executes the constraint to match
## literature constraints limit 6 to 80 number of realistic
## nodal connections in the graph.
def build_connected_graph(axonal_graph):
  ## Build connected graph where each node has at least 6 and
  ## at most 80 connections
  connected_graph = Graph( )
  for node_id, connections in axonal_graph.nodes.items( ):
      ## Shuffle connections to randomize selection process
      random.shuffle(connections)
      num_connections = min(max(6, len(connections)), 80)
      connected_graph.add_node(node_id,
connections[:num_connections])
  return connected_graph
## Main python script - the main function calls upon the helper
functions and executes the code.
## the main function can also be in form of, e.g., input file or
## Fortran sub-routine script.
axon_network = build_axonal_network( )
apply_electrical_boundary_conditions(axon_network)
## this helps use the graph in the multi-modal network as modal
## input type electrical channel (NumPy array or JSON data for
## defining connection information)
connected_graph = build_connected_graph(axon_network)
save_graph_to_file(connected_graph, ‘axon_network_graph.json’)
```

1. A computer-implemented method for physics-based multi-modal prediction of composite properties, the computer-implemented method comprising:
transforming a first mode input into at least one material property definition of at least one physics-based model, the first mode input representing at least one mechanical characteristic of a composite sample;
transforming a second mode input into at least one phase volume parameter of the at least one physics-based model, the second mode input representing at least one morphological characteristic of the composite sample;
transforming a third mode input into at least one electrical conductivity parameter of the at least one physics-based model, the third mode input associated with the composite sample; and
using the at least one physics-based model, predicting at least one property of the composite sample.

2. (canceled)

3. The computer-implemented method of claim 1, wherein the at least one physics-based model includes at least one finite element (FE) model, and wherein the predicting includes:
via a FE solver, using the at least one FE model, predicting the at least one property.

4. The computer-implemented method of claim 1, wherein the predicted at least one property of the composite sample includes at least one of a mechanical property, an electrical property, and a biochemical property.

5. The computer-implemented method of claim 1, further comprising:
based on the first mode input, the second mode input, and the third mode input, via at least one generative ML/AI model, producing a set of synthesized physics-based models;
wherein predicting the at least one property of the composite sample is performed using the set of synthesized physics-based models.

6. The computer-implemented method of claim 5, wherein the at least one generative ML/AI model includes at least one of a Retrieval-Augmented Generation (RAG) model and a generative adversarial network (GAN) model.

7. The computer-implemented method of claim 5, wherein the producing is based on a first constraint set, a second constraint set, and a third constraint set, the first constraint set corresponding to the first mode input, the second constraint set corresponding to the second mode input, the third constraint set corresponding to the third mode input.

8. (canceled)

9. A computer-implemented method for hybrid multi-modal prediction of composite properties, the computer-implemented method comprising:
encoding, in at least one input variable of a machine learning (ML) model, based on a first mode input, at least one material property definition, the first mode input representing at least one mechanical characteristic of a composite sample, the ML model being trained to predict composite properties based on first mode inputs, second mode inputs, and third mode inputs;
encoding, in the at least one input variable of the ML model, based on a second mode input, at least one phase volume parameter, the second mode input representing at least one morphological characteristic of the composite sample;
encoding, in the at least one input variable of the ML model, based on a third mode input, at least one electrical conductivity parameter, the third mode input associated with the composite sample; and
using the ML model, predicting at least one property of the composite sample.

10. The computer-implemented method of claim 9, further comprising:
training the ML model based on multiple training data tuples, each of the multiple training data tuples including (i) a first mode training input, (ii) a second mode training input, (iii) a third mode training input, and (iv) at least one training property.

11. The computer-implemented method of claim 10, further comprising:
generating at least one training property of a given training data tuple of the multiple training data tuples by:
transforming the first mode training input of the given training data tuple into at least one material property definition of at least one physics-based model, the first mode training input representing at least one mechanical characteristic of a composite training sample;
transforming the second mode training input of the given training data tuple into at least one phase volume parameter of the at least one physics-based model, the second mode training input representing at least one morphological characteristic of the composite training sample;
transforming the third mode training input of the given training data tuple into at least one electrical conductivity parameter of the at least one physics-based model, the third mode training input associated with the composite training sample; and
using the at least one physics-based model, predicting the at least one training property of the given training data tuple.

12. The computer-implemented method of claim 9, wherein the predicted at least one property includes at least one micro-scale property, and further comprising:
using at least one homogenization model, transforming the at least one micro-scale property into at least one macro-scale property of the composite sample.

13. (canceled)

14. The computer-implemented method of claim 9, further comprising:
using an optimization model, constructing a design space based on the predicted at least one property.

15. The computer-implemented method of claim 14, further comprising:
based on the constructed design space, synthesizing a composite material candidate design.

16. The computer-implemented method of claim 15, further comprising:
comparing the synthesized composite material candidate design and the composite sample; and
based on a result of the comparing, modifying at least one of the first mode input, the second mode input, and the third mode input.

17. (canceled)

18. The computer-implemented method of claim 14, wherein the optimization model includes at least one of: a genetic model, a grid search model, a space-filling model, a particle swarm model, another multi-objective optimization model, and a generative ML/AI model.

19. The computer-implemented method of claim 14, wherein synthesizing the composite material candidate design includes synthesizing one or more composite material candidate designs, and further comprising:
using at least one generative ML/AI model, transforming the one or more composite material candidate designs synthesized into one or more optimized composite material candidate designs.

20. The computer-implemented method of claim 19, wherein transforming the one or more composite material candidate designs synthesized is based on at least one prompt received from a user.

21. (canceled)

22. The computer-implemented method of claim 9, wherein the ML model is a neural network model, and wherein the at least one input variable includes an input layer of the neural network model.

23. (canceled)

24. The computer-implemented method of claim 9, further comprising:
encoding, in the at least one input variable of the ML model, based on a fourth mode input, at least one additional parameter, the fourth mode input including at least one of: a biochemical data input, a large language model (LLM) based input, a natural language processing (NLP) based input, a time series input, a sensor input, an equation based input, a video input, a radiation data input, and a patient history input;
wherein the ML model is further trained to predict composite properties based on fourth mode inputs.

25. (canceled)

26. The computer-implemented method of claim 9, wherein the third mode input includes (i) at least one graph interconnect characteristic of the composite sample or (ii) a growth model corresponding to the composite sample.

27. The computer-implemented method of claim 26, further comprising:
configuring at least one of: (i) a graph branch length parameter, (ii) a branching proliferation criterion, (iii) a branching expansion criterion, and (iv) an interaction parameter, for the growth model.

28. (canceled)

29. (canceled)
